(19) United States
(12) Patent Application Publication
(10) Pub. No.: US 2025/0294890 A1
(43) Pub. Date: Sep. 18, 2025

(54) INTEGRATED CIRCUIT DEVICE

(71) Applicant: Samsung Electronics Co., Ltd., Suwon-si (KR)

(72) Inventors: Jongsoon Park, Suwon-si (KR); Yongjin Kwon, Suwon-si (KR); Backkyu Choi, Suwon-si (KR); Hyonwook Ra, Suwon-si (KR); Seungchul Oh, Suwon-si (KR)

(21) Appl. No.: 18/941,008

(22) Filed: Nov. 8, 2024

(30) Foreign Application Priority Data
Mar. 13, 2024 (KR) 10-2024-0035431
May 3, 2024 (KR) 10-2024-0059409

(51) Int. Cl. H01L 27/02; H01L 27/08

(52) U.S. Cl. CPC H10D 89/60; H10D 84/209

(57) ABSTRACT

An integrated circuit device includes a lower insulating film on a substrate, a lower metal wiring layer extending through the lower insulating film, an insulating protective structure on a top surface of each of the lower metal wiring layer and the lower insulating film, an upper insulating film on the insulating protective structure, an upper metal wiring layer on the upper insulating film, and a conductive contact plug extending through the upper insulating film and the insulating protective structure in a vertical direction and contacting each of the lower metal wiring layer and the upper metal wiring layer. The insulating protective structure includes a plurality of first silicon carbonitride (SiCN) films and at least one first oxide thin film. Each first oxide thin film is between two adjacent ones of the plurality of first SiCN films.

### CROSS-REFERENCE TO RELATED APPLICATION(S)

This application is based on and claims priority under 35 U.S.C. § 119 to Korean Patent Applications Nos. 10-2024-0035431 and 10-2024-0059409, filed on Mar. 13, 2024 and May 3, 2024, respectively, in the Korean Intellectual Property Office, the disclosures of which are incorporated by reference herein in their entireties.

### BACKGROUND

The inventive concept relates generally to an integrated circuit (IC) device, and more particularly, to an IC device including a metal wiring layer.

The downscaling of IC devices has rapidly progressed due to the development of electronics technology. Thus, metal wiring layers included in the IC devices are being reduced in terms of linewidth and pitch. Accordingly, it is necessary to improve the electrical reliability of metal wiring layers.

### SUMMARY

The inventive concept provides an integrated circuit (IC) device having a structure capable of improving the electrical reliability of metal wiring layers.

According to an aspect of the inventive concept, there is provided an IC device including a lower insulating film on a substrate, a lower metal wiring layer passing through (i.e., extending in) the lower insulating film, an insulating protective structure covering a top surface of each of the lower metal wiring layer and the lower insulating film, an upper insulating film on the insulating protective structure, an upper metal wiring layer on the upper insulating film, and a conductive contact plug passing through the upper insulating film and the insulating protective structure in a vertical direction and contacting each of the lower metal wiring layer and the upper metal wiring layer, wherein the insulating protective structure includes a plurality of first silicon carbonitride (SiCN) films and at least one first oxide thin film, each of which is between two adjacent ones of the plurality of first SiCN films.

According to another aspect of the inventive concept, there is provided an IC device including a lower insulating film on a substrate, a plurality of lower metal wiring layers passing through (i.e., extending in) the lower insulating film, the plurality of lower metal wiring layers being spaced apart from each other, a lower insulating protective structure on a top surface of each of the plurality of lower metal wiring layers and the lower insulating film, an upper insulating film on the lower insulating protective structure, an upper metal wiring layer on the upper insulating film, a conductive contact plug passing through the upper insulating film and the insulating protective structure in a vertical direction, the conductive contact plug contacting each of a corresponding one of the plurality of lower metal wiring layers and the upper metal wiring layer, and an upper insulating protective structure covering a top surface of each of the upper metal wiring layer and the upper insulating film, wherein each of the lower insulating protective structure and the upper insulating protective structure includes a plurality of SiCN films and at least one oxide thin film, each of which is between two adjacent ones of the plurality of SiCN films.

According to another aspect of the inventive concept, there is provided an IC device including a lower insulating film on a substrate, a plurality of lower metal wiring layers passing through (i.e., extending in) the lower insulating film, the plurality of lower metal wiring layers being spaced apart from each other, a lower insulating protective structure on a top surface of each of the plurality of lower metal wiring layers and the lower insulating film, an upper insulating film covering the lower insulating protective structure, an upper metal wiring layer on the upper insulating film, a conductive contact plug passing through the upper insulating film and the insulating protective structure in a vertical direction perpendicular to an upper surface of the substrate, the conductive contact plug contacting each of a corresponding one of the plurality of lower metal wiring layers and the upper metal wiring layer, an upper insulating protective structure covering a top surface of each of the upper metal wiring layer and the upper insulating film, a thin film resistor on the upper insulating protective structure, the thin film resistor being spaced apart from the upper metal wiring layer with the upper insulating protective structure therebetween in the vertical direction, and an insulating resistor protective structure contacting a top surface of the thin film resistor, wherein each of the lower insulating protective structure, the upper insulating protective structure, and the insulating resistor protective structure includes a plurality of SiCN films and at least one oxide thin film, each of which is between two adjacent ones of the plurality of SiCN films.

### BRIEF DESCRIPTION OF THE DRAWINGS

Embodiments will be more clearly understood from the following detailed description taken in conjunction with the accompanying drawings, wherein like reference numerals (when used) indicate corresponding elements throughout the several views, and in which:

FIG. 1 is a schematic plan layout diagram of an integrated circuit (IC) device according to embodiments;

FIG. 2 is a schematic cross-sectional view taken along line X1-X1′ of FIG. 1;

FIGS. 3 and 4 are schematic cross-sectional views of an IC device according to embodiments;

FIGS. 5 and 6 are schematic cross-sectional views of IC devices according to embodiments;

FIG. 7 is a schematic plan layout diagram of an IC device according to embodiments;

FIG. 8 is a schematic cross-sectional view taken along line X1-X1′ of FIG. 7;

FIG. 9 is a schematic cross-sectional view of an IC device according to embodiments;

FIG. 10 is a schematic cross-sectional view of an IC device according to embodiments;

FIGS. 11A to 11H are schematic cross-sectional views depicting a sequence of intermediate processes in an example method of manufacturing an IC device, according to embodiments;

FIG. 12 is a flowchart of an example method of forming an insulating protective structure according to a method of manufacturing an IC device, according to embodiments; and

FIGS. 13A to 13E are schematic cross-sectional views depicting a sequence of intermediate processes in an example method of manufacturing an IC device, according to embodiments.

### DETAILED DESCRIPTION

Hereinafter, embodiments will be described in detail with reference to the accompanying drawings. The same reference numerals are used to denote the same elements in the drawings, and repeated descriptions thereof are omitted.

As used herein, ordinal terms such as “first” and “second” are used herein merely to describe a variety of constituent elements, but the constituent elements are not limited by the terms. Such terms are used only for the purpose of distinguishing one constituent element from another constituent element. For example, without departing from the right scope of various embodiments described below, a first constituent element, a second constituent element, and a third constituent element may each be referred to only as a “constituent element” and, unless otherwise defined, a first constituent element may be referred to as a second constituent element, and vice versa.

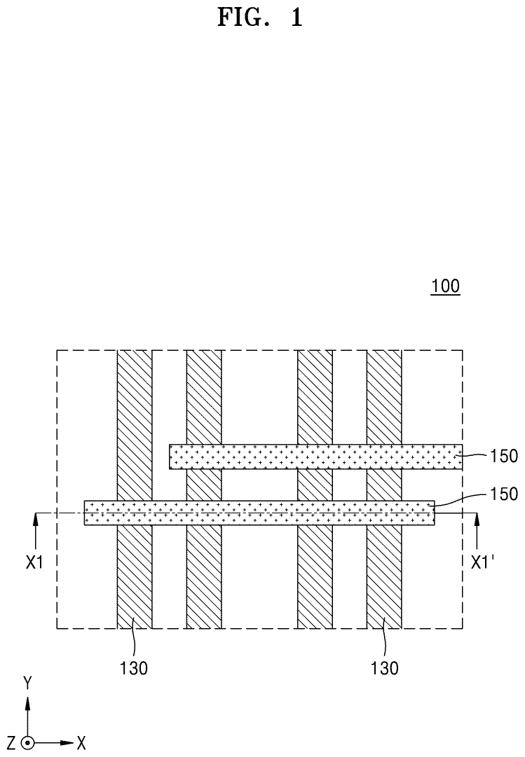

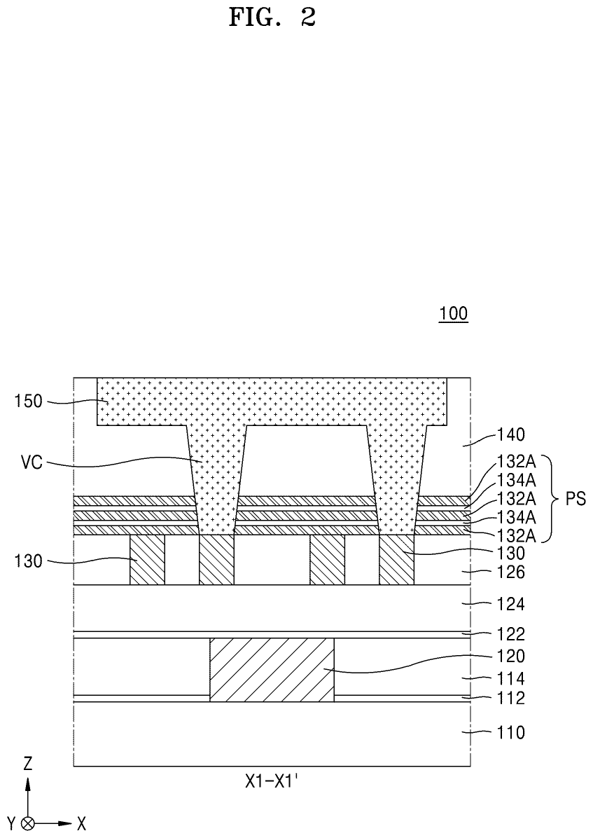

FIG. 1A is a schematic plan layout diagram of an integrated circuit (IC) device 100 according to embodiments. FIG. 2 is a schematic cross-sectional view taken along line X1-X1′ of FIG. 1.

Referring to FIGS. 1 and 2, the IC device 100 may include a lower structure on a substrate 110. The lower structure may include a first lower etch stop film 112, a first interlayer insulating film 114, a second lower etch stop film 122, and a second interlayer insulating film 124, which are sequentially on the substrate 110 in a vertical direction (Z direction) perpendicular to an upper surface of the substrate 110, and a conductive structure 120 passing through (i.e., extending in) the first interlayer insulating film 114 and the first lower etch stop film 112 in the vertical direction (Z direction).

The substrate 110 may include a semiconductor, such as silicon (Si) or germanium (Ge), or a compound semiconductor, such as silicon germanium (SiGe), silicon carbide (SiC), gallium arsenide (GaAs), indium arsenide (InAs), or indium phosphide (InP), although embodiments are not limited thereto. The substrate 110 may include a conductive region (not explicitly shown). The conductive region may include a doped well, a doped structure, or a conductive layer. The substrate 110 may include circuit elements (not explicitly shown), such as a gate structure, an impurity region, and a contact plug.

Each of the first interlayer insulating film 114 and the second interlayer insulating film 124 may include a silicon oxide film. For example, each of the first interlayer insulating film 114 and the second interlayer insulating film 124 may include a silicon-oxide-based material, such as plasma enhanced oxide (PEOX), tetraethyl orthosilicate (TEOS), boro TEOS (BTEOS), phosphorous TEOS (PTEOS), boro phospho TESO (BPTEOS), boro silicate glass (BSG), phospho silicate glass (PSG), and boro PSG (BPSG), although embodiments are not limited thereto. In other embodiments, each of the first interlayer insulating film 114 and the second interlayer insulating film 124 may have a low-k dielectric film (e.g., a SiOC film or a SiCOH film) having a low dielectric constant K of about 2.2 to about 3.0.

Each of the first lower etch stop film 112 and the second lower etch stop film 122 may include a material having a different etch selectivity from a constituent material of each of the first interlayer insulating film 114 and the second interlayer insulating film 124. For example, each of the first lower etch stop film 112 and the second lower etch stop film 122 may include a silicon nitride film, a carbon-doped silicon nitride film, or a carbon-doped silicon oxynitride film. In embodiments, each of the first lower etch stop film 112 and the second lower etch stop film 122 may include an insulating metal oxide film, an insulating metal nitride film, or a combination thereof. For example, the first lower etch stop film 112 and the second lower etch stop film 122 may include an aluminum oxide film (AlO film), an aluminum nitride film (AlN film), or a combination thereof.

In embodiments, the conductive structure 120 may be a wiring layer including a metal film and a conductive barrier film surrounding the metal film. The term “surrounding” (or “surrounds,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles. In the conductive structure 120, the metal film may include, for example, copper (Cu), tungsten (W), molybdenum (Mo), ruthenium (Ru), cobalt (Co), aluminum (Al), or a combination thereof, and the conductive barrier film may include, for example, a titanium nitride (TiN) film, a tantalum nitride (TaN) film, a cobalt (Co) film, or a combination thereof, without being limited thereto. In embodiments, the conductive structure 120 may be electrically connected to the conductive region formed in the substrate 110. The term “connected” (or “connecting,” or like terms, such as “contact” or “contacting”), as may be used herein, is intended to refer to a physical and/or electrical connection between two or more elements, and may include other intervening elements. As used herein, the term “and/or” includes any and all combinations of one or more of the associated listed items. In other embodiments, the conductive structure 120 may be connected to a source/drain region (not shown) or a gate electrode (not shown) of a transistor formed in the substrate 110.

A lower insulating film 126 may be on the second interlayer insulating film 124, and a plurality of lower metal wiring layers 130 may pass through the lower insulating film 126 in the vertical direction (Z direction). The plurality of lower metal wiring layers 130 may be spaced apart from each other in a first lateral (i.e., horizontal) direction (X direction), parallel to the upper surface of the substrate 110, and extend lengthwise in a second lateral direction (Y direction), which intersects the first lateral direction (X direction). In embodiments, the first lateral direction (X direction) may be perpendicular to the second lateral direction (Y direction). The plurality of lower metal wiring layers 130 may extend parallel to each other in the second lateral direction (Y direction).

A top surface of each of the plurality of lower metal wiring layers 130 and the lower insulating film 126 may be covered by an insulating protective structure PS. The term “covered” (or “covering,” “covers,” or like terms), as may be used herein, is intended to broadly refer to an element, structure or layer that is on or over another element, structure or layer, either directly or with one or more other intervening elements, structures or layers therebetween. The insulating protective structure PS may be covered by an upper insulating film 140. As used herein, the insulating protective structure PS may also be referred to as a lower insulating protective structure.

A bottom surface of the insulating protective structure PS may be in contact with the top surface of each of the plurality of lower metal wiring layers 130 and the lower insulating film 126, and a top surface of the insulating protective structure PS may be in contact with a bottom surface of the upper insulating film 140. As used herein, a bottom surface of a component refers to a surface facing the substrate 110, and a top surface of the component refers to a surface opposite to the bottom surface of the component. For example, the bottom surface of the insulating protective structure PS refers to a surface facing the substrate 110, and the top surface of the insulating protective structure PS refers to a surface opposite to the bottom surface of the insulating protective structure PS.

The insulating protective structure PS may include a plurality of SiCN films 132A, which are sequentially stacked on the top surface of each of the lower insulating film 126 and the plurality of lower metal wiring layers 130 in a vertical direction (Z direction), and at least one oxide thin film 134A, each of which is between two adjacent ones of the plurality of SiCN films 132A. FIG. 2 illustrates an example in which the insulating protective structure PS includes three SiCN films 132A sequentially stacked in the vertical direction (Z direction) and two oxide thin films 134A, each of which is between two adjacent ones of the three SiCN films 132A, but the inventive concept is not limited to the example shown in FIG. 2. The number of SiCN films 132A and the number of oxide thin films 134A in the insulating protective structure PS may be variously selected as needed. In embodiments, the oxide thin film 134A may include a silicon oxide film. As used herein, the SiCN film 132A may be referred to as a first SiCN film, and the oxide thin film 134A may also be referred to as a first oxide thin film.

In the insulating protective structure PS, a thickness of the oxide thin film 134A in the vertical direction (Z direction) may be less than a thickness of each of the plurality of SiCN films 132A in the vertical direction (Z direction). In embodiments, in the insulating protective structure PS, the thickness of each of the plurality of SiCN films 132A in the vertical direction (Z direction) may be about 4 times to about 40 times the thickness of each of the oxide thin film 134A in the vertical direction (Z direction). For example, in the insulating protective structure PS, a thickness of each of the plurality of SiCN films 132A in the vertical direction (Z direction) may be in a range of about 2 nanometers (nm) to about 10 nm, and a thickness of each of the plurality of oxide thin films 134A in the vertical direction (Z direction) may be in a range of about 0.3 nm to about 0.5 nm, without being limited thereto.

In one or more embodiments, in the insulating protective structure PS, each of the plurality of SiCN films 132A may include about 40 atomic percent (at %) to about 60 at % of silicon (Si) atoms, about 20 at % to about 30 at % of carbon (C) atoms, and about 20 at % to about 30 at % of nitrogen (N) atoms.

In embodiments, the plurality of SiCN films 132A included in the insulating protective structure PS may have the same content ratio of carbon (C) atoms. In other embodiments, a content ratio of C atoms in at least one of the plurality of SiCN films 132A may be different from a content ratio of C atoms in another one of the plurality of SiCN films 132A. In an example, from among the plurality of SiCN films 132A, the SiCN film 132A that is closest to the substrate 110 in the vertical direction (Z direction) may be at a higher content ratio of C atoms than other SiCN films 132A. In another example, from among the plurality of SiCN films 132A, the SiCN film 132A that is farthest from the substrate 110 in the vertical direction (Z direction) may be at a higher content ratio of C atoms than the other SiCN films 132A. In still another example, from among the plurality of SiCN films 132A, the SiCN film 132A that is closest to the substrate 110 in the vertical direction (Z direction) and the SiCN film 132A that is farthest from the substrate 110 in the vertical direction (Z direction) may be at lower content ratios of C atoms than other SiCN films 132A.

An upper insulating film 140 may be on the insulating protective structure PS. The upper insulating film 140 may be spaced apart from the lower insulating film 126 and the plurality of lower metal wiring layers 130 with the insulating protective structure PS therebetween in the vertical direction (Z direction).

A plurality of upper metal wiring layers 150 may be on the upper insulating film 140. Each of the plurality of upper metal wiring layers 150 may overlap at least one lower metal wiring layer 130 selected from the plurality of lower metal wiring layers 130 in the vertical direction (Z direction). The term “overlap” (or “overlapping,” or like terms), as may be used herein, is intended to broadly refer to a first element that intersects with at least a portion of a second element in the vertical direction (i.e., Z-direction), but does not require that the first and second elements be completely aligned with one another in a horizontal plane (i.e., X-direction and/or Y-direction). Each of the plurality of upper metal wiring layers 150 may extend lengthwise in a first lateral direction (X direction).

A plurality of conductive contact plugs VC may pass through the upper insulating film 140 and the insulating protective structure PS in the vertical direction (Z direction). Each of the plurality of conductive contact plugs VC may extend in the vertical direction (Z direction) between a selected one of the plurality of upper metal wiring layers 150 and a selected one of the plurality of lower metal wiring layers 130 and contact each of the selected one upper metal wiring layer 150 and the selected lower metal wiring layer 130. As shown in FIG. 2, a selected one of the plurality of conductive contact plugs VC may be integrally connected to the upper metal wiring layer 150 connected to the at least one conductive contact plug VC. Each of the plurality of conductive contact plugs VC may have a width in a lateral direction (e.g., the first lateral direction (X direction)), which gradually reduces as the contact plug VC extends toward the substrate 110 from the upper metal wiring layer 150 corresponding thereto. The plurality of SiCN films 132A and the plurality of oxide thin films 134A in the insulating protective structure PS may be in contact with a sidewall of each of the plurality of conductive contact plugs VC.

Constituent materials of the lower insulating film 126 and the upper insulating film 140 are respectively and substantially be the same as constituent materials of the first interlayer insulating film 114 and the second interlayer insulating film 124. Each of the plurality of lower metal wiring layers 130, the plurality of upper metal wiring layers 150, and the plurality of conductive contact plugs VC may include a metal film, a conductive metal nitride film, or a combination thereof. In embodiments, each of the plurality of lower metal wiring layers 130, the plurality of upper metal wiring layers 150, and the plurality of conductive contact plugs VC may include a metal plug and a conductive barrier film surrounding a sidewall and a bottom surface of the metal plug. The metal plug may include, for example, copper (Cu), tungsten (W), molybdenum (Mo), ruthenium (Ru), cobalt (Co), aluminum (Al), or a combination thereof. For example, the metal plug may include copper (Cu). The conductive barrier film may include, for example, a TiN film, a TaN film, a Co film, or a combination thereof. For example, when the metal plug includes Cu, the conductive barrier film may have a multilayered structure including a TaN film and a Co film, without being limited thereto.

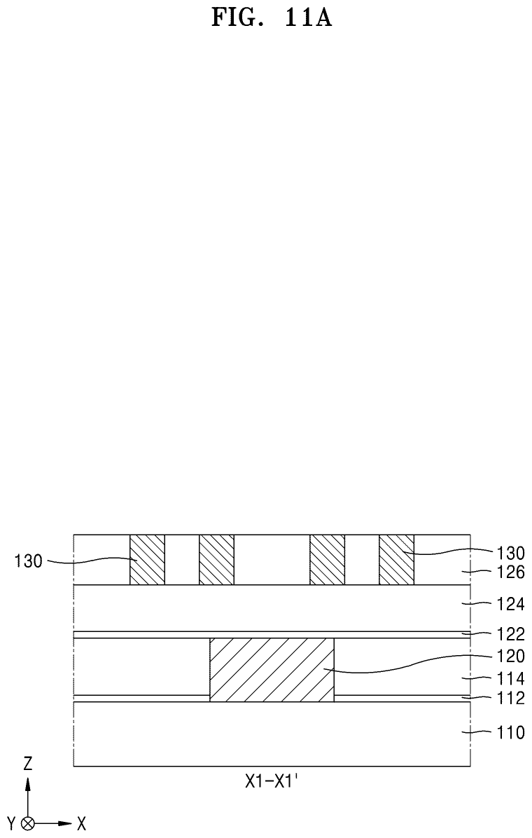

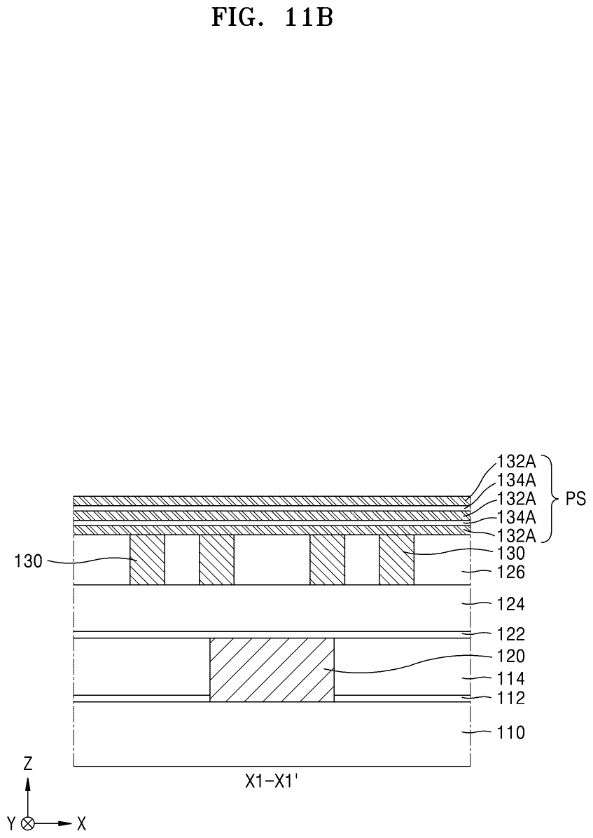

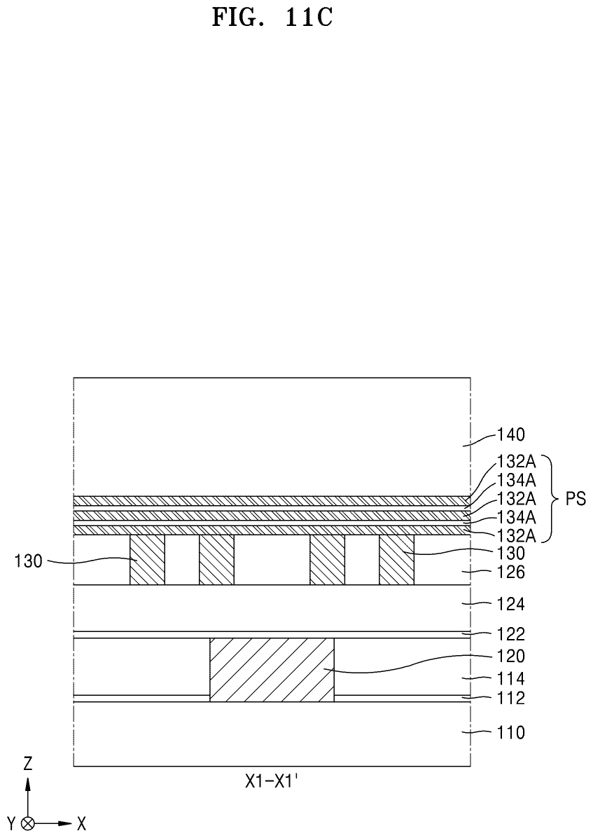

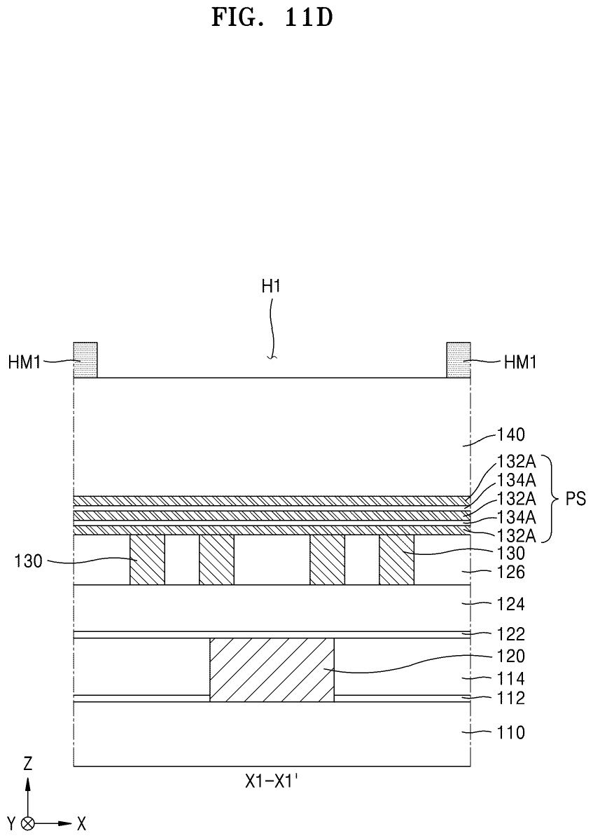

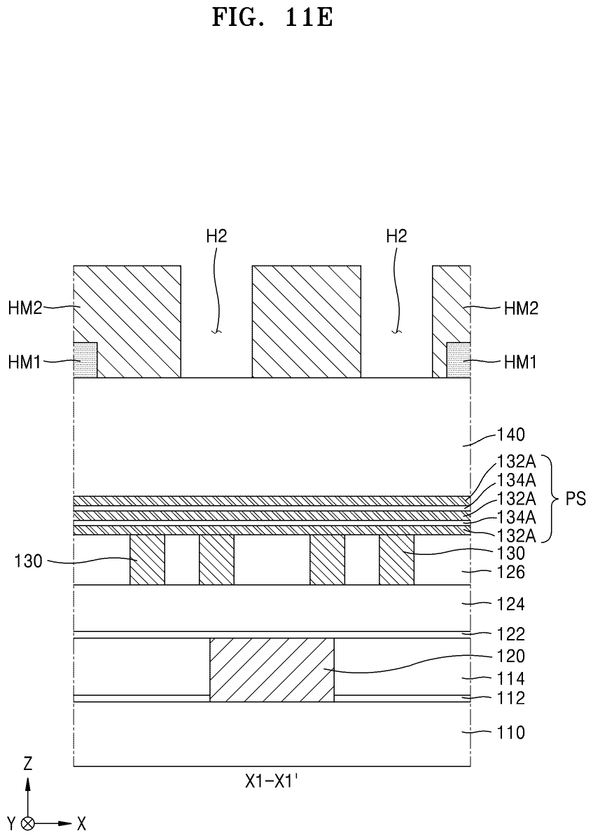

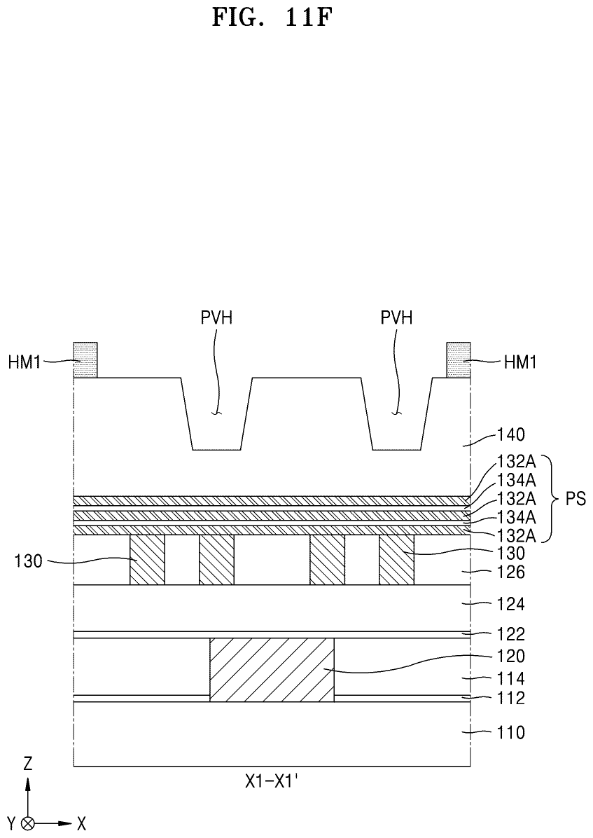

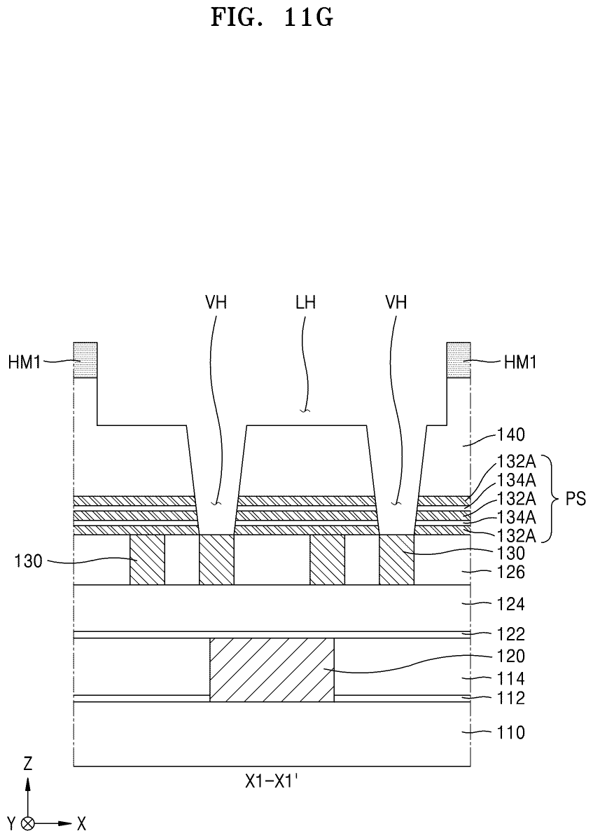

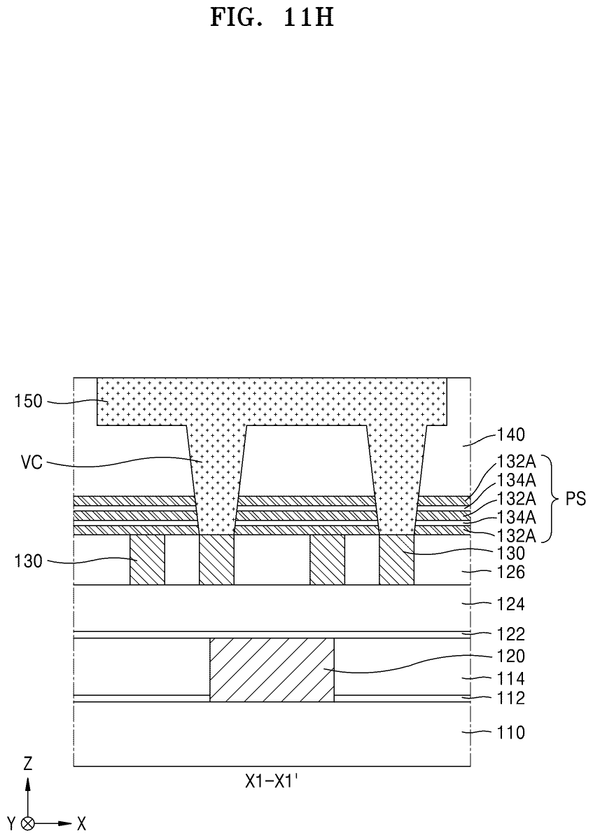

In the IC device 100 shown in FIGS. 1 and 2, the insulating protective structure PS having a multilayered structure covering the top surface of each of the plurality of lower metal wiring layers 130 and the lower insulating film 126 may protect the plurality of lower metal wiring layers 130 during the manufacture of the IC device 100. In addition, an etching process of forming a plurality of via holes (e.g., a plurality of via holes VH shown in FIG. 11G) exposing the plurality of lower metal wiring layers 130 may be performed to form the plurality of conductive contact plugs VC, which pass through the insulating protective structure PS and the upper insulating film 140 located thereon and be connected to the plurality of lower metal wiring layers 130. The term “exposing” (or “exposed,” or like terms) may be used herein to describe relationships between elements and/or with reference to intermediate processes in fabricating an integrated circuit device, but may not require exposure of a particular element in the completed device. Likewise, the term “not exposed” may be used to describe relationships between elements and/or with reference to intermediate processes in fabricating an integrated circuit device, but may not require a particular element to be unexposed in the completed device. In this case, when the plurality of via holes VH are formed while the top surface of each of the plurality of lower metal wiring layers 130 is covered by the insulating protective structure PS including the plurality of SiCN films 132A and the plurality of oxide thin films 134A, an etch selectivity may further increase due to the insulating protective structure PS during the etching process of forming the plurality of via holes VH.

As a comparative example, when a comparative etch stop film including a single SiCN film is adopted instead of the insulating protective structure PS, to improve an etch selectivity, it may be necessary to increase a thickness of the comparative etch stop film during the etching of the upper insulating film 140 and the comparative etch stop film by using a metal-containing hard mask (hereinafter, a metal hard mask) as an etch mask. However, increasing the thickness of the comparative etch stop film may be disadvantageous for improving the integration density of the IC device 100.

According to one or more embodiments of the inventive concept, the insulating protective structure PS may include the plurality of SiCN films 132A, which are sequentially stacked on the top surface of each of the plurality of lower metal wiring layers 130 in the vertical direction (Z direction), and the at least one oxide thin film 134A, each of which is between two adjacent ones of the plurality of SiCN films 132A. As described above, the etching process of forming the plurality of via holes VH may be performed while the top surface of each of the plurality of lower metal wiring layers 130 is covered by the insulating protective structure PS in which the plurality of SiCN films 132A and the at least one oxide thin film 134A, which may include different materials from each other, are alternately stacked one-by-one in the vertical direction (Z direction). In this case, an etch stop point may be effectively determined due to the insulating protective structure PS during the etching process, and the plurality of lower metal wiring layers 130 may be protected by the insulating protective structure PS. Thus, there may be no concern that each of the plurality of lower metal wiring layers 130 is damaged due to the etching process. Therefore, the reliability of electrical connection between the lower metal wiring layer 130 and the upper metal wiring layer 150 through the conductive contact plug VC may improve, and the reliability of the IC device 100 may improve.

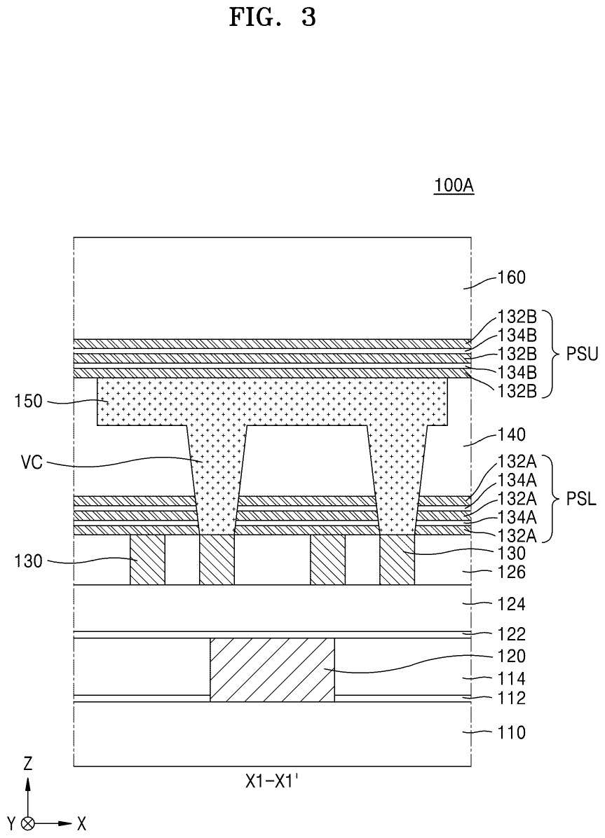

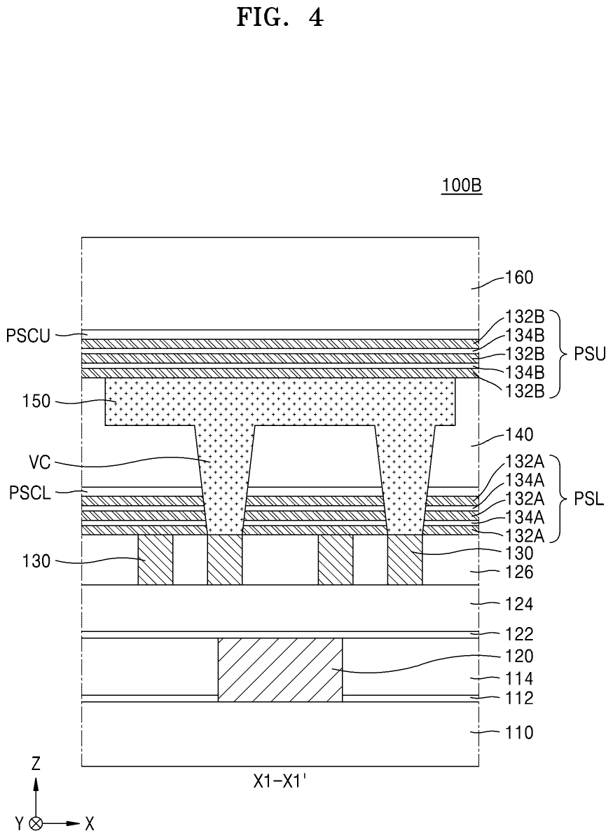

FIGS. 3 and 4 are schematic cross-sectional views of IC devices 100A and 100B according to embodiments. FIGS. 3 and 4 each illustrate components corresponding to a cross-section taken along line X1-X1′ of FIG. 1. In FIGS. 3 and 4, the same reference numerals are used to denote the same elements as in FIGS. 1 and 2, and detailed descriptions thereof are omitted.

Referring to FIG. 3, the IC device 100A may substantially have the same configuration as the IC device 100 described with reference to FIGS. 1 and 2. However, the IC device 100A may include a lower insulating protective structure PSL covering a top surface of each of a lower insulating film 126 and a plurality of lower metal wiring layers 130, an upper insulating protective structure PSU covering a top surface of each of an upper metal wiring layer 150 and an upper insulating film 140, and an interlayer insulating film 160 covering a top surface of the upper insulating protective structure PSU.

The lower insulating protective structure PSL may have the same configuration as the insulating protective structure PS described with reference to FIG. 2. The upper insulating protective structure PSU may include a plurality of SiCN films 132B, which are sequentially stacked on the top surface of each of the upper metal wiring layer 150 and the upper insulating film 140 in a vertical direction (Z direction), and at least one oxide thin film 134B, each of which is between two adjacent ones of the plurality of SiCN films 132B. FIG. 3 illustrates an example in which the upper insulating protective structure PSU includes three SiCN films 132B sequentially stacked in the vertical direction (Z direction) and two oxide thin films 134B, each of which is between two adjacent ones of the three SiCN films 132B, but the inventive concept is not limited to the example shown in FIG. 3. The number of SiCN films 132B and the number of oxide thin films 134B in the upper insulating protective structure PSU may be variously selected as needed. In embodiments, the oxide thin film 134B may include a silicon oxide film. As used herein, the SiCN film 132B may also be referred to as a second SiCN film, and the oxide thin film 134B may also be referred to as a second oxide thin film.

A bottom surface of the upper insulating protective structure PSU may be in contact with the top surface of each of the upper metal wiring layer 150 and the upper insulating film 140, and a top surface of the upper insulating protective structure PSU may be in contact with a bottom surface of the interlayer insulating film 160.

Detailed configurations of the plurality of SiCN films 132B and a plurality of oxide thin films 134B in the upper insulating protective structure PSU are respectively and substantially the same as the plurality of SiCN films 132A and the plurality of oxide thin films 134A in the insulating protective structure PS, which have been described with reference to FIG. 2. A constituent material of the interlayer insulating film 160 may substantially be the same as a constituent material of each of the first interlayer insulating film 114 and the second interlayer insulating film 124, which has been described with reference to FIG. 2. For example, the interlayer insulating film 160 may have a low-k dielectric film (e.g., a SiOC film or a SiCOH film) having a low dielectric constant of about 2.2 to about 3.0.

Referring to FIG. 4, the IC device 100B may substantially have the same configuration as the IC device 100A described with reference to FIG. 3. However, the IC device 100B may further include a lower capping insulating film PSCL between a lower insulating protective structure PSL and the upper insulating film 140 and an upper capping insulating film PSCU between the upper insulating protective structure PSU and the interlayer insulating film 160.

A bottom surface of the lower capping insulating film PSCL may be in contact with a top surface of the lower insulating protective structure PSL, and a top surface of the lower capping insulating film PSCL may be in contact with a bottom surface of the upper insulating film 140. A bottom surface of the upper capping insulating film PSCU may be in contact with a top surface of the upper insulating protective structure PSU, and a top surface of the upper capping insulating film PSCU may be in contact with a bottom surface of the interlayer insulating film 160.

Each of the lower capping insulating film PSCL and the upper capping insulating film PSCU may include, for example, a silicon oxide film, an aluminum oxide film, or a combination thereof. A thickness of each of the lower capping insulating film PSCL and the upper capping insulating film PSCU in the vertical direction (Z direction) may be in a range of about 2 nm to about 10 nm, without being limited thereto. In some embodiments, any one of the lower capping insulating film PSCL and the upper capping insulating film PSCU may be omitted.

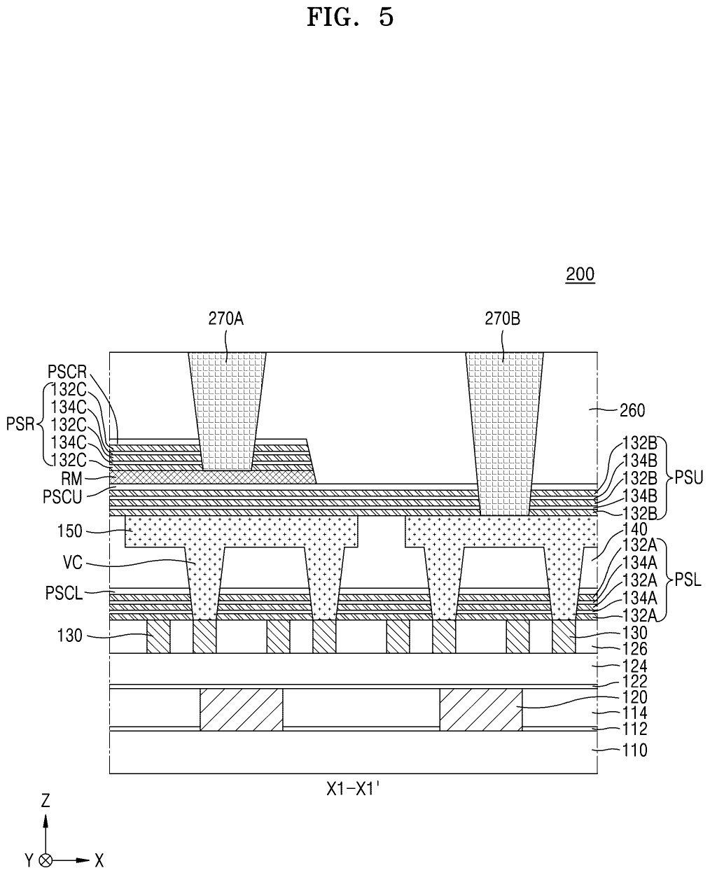

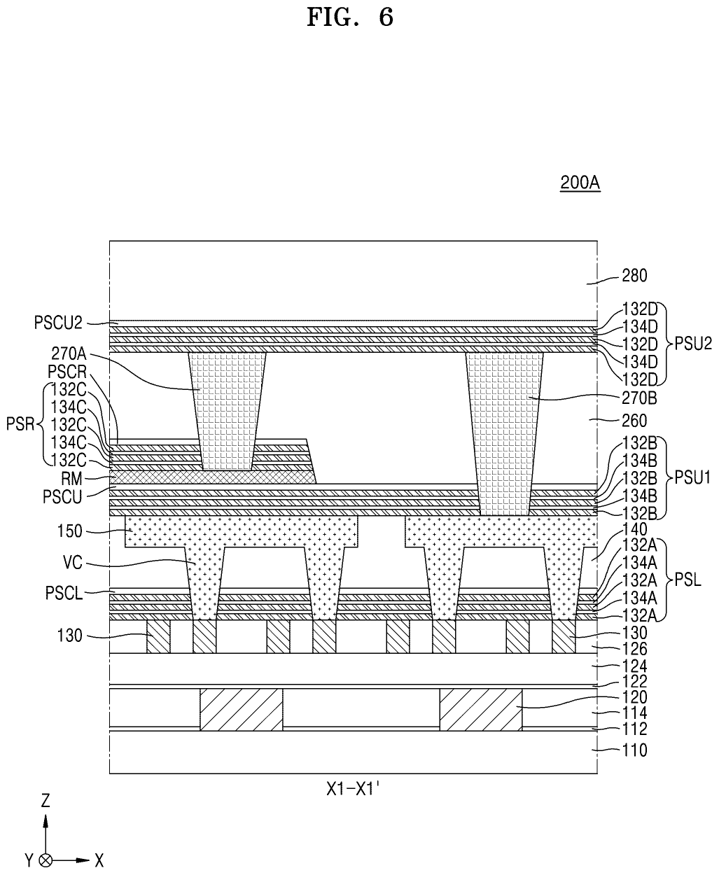

FIGS. 5 and 6 are schematic cross-sectional views of IC devices 200 and 200A according to embodiments. FIGS. 5 and 6 each illustrate components corresponding to a cross-section taken along line X1-X1′ of FIG. 1. In FIGS. 5 and 6, the same reference numerals are used to denote the same elements as in FIGS. 1 to 4, and detailed descriptions thereof are omitted.

Referring to FIG. 5, the IC device 200 may substantially have the same configuration as the IC device 100B described with reference to FIG. 4. However, the IC device 200 may further include a thin film resistor RM on an upper insulating protective structure PSU and an insulating resistor protective structure PSR covering a top surface of a thin film resistor RM. FIG. 5 illustrates a plurality of upper metal wiring layers 150, which extend lengthwise (i.e., longitudinally) in a first lateral direction (X direction) and are spaced apart from each other in the first lateral direction (X direction), and a plurality of conductive contact plugs VC, each of which is integrally connected to a corresponding one of the plurality of upper metal wiring layers 150.

The thin film resistor RM may be spaced apart from the upper metal wiring layer 150 in a vertical direction (Z direction) with the upper insulating protective structure PSU and an upper capping insulating film PSCU therebetween. A bottom surface of the thin film resistor RM may be in contact with a top surface of the upper capping insulating film PSCU, and a top surface of the thin film resistor RM may be in contact with a bottom surface of the insulating resistor protective structure PSR.

The thin film resistor RM may include, for example, a metal, a conductive metal nitride, or a combination thereof. In embodiments, the thin film resistor RM may include Cu, W, Mo, Ru, Co, Al, TiN, TaN, or a combination thereof. For example, the thin film resistor RM may include TiN, TaN, or a combination thereof, without being limited thereto. In embodiments, the thin film resistor RM may have a thickness of about 2 nm to about 20 nm in the vertical direction (Z direction), without being limited thereto.

The insulating resistor protective structure PSR may include a plurality of SiCN films 132C, which are sequentially stacked on the top surface of the thin film resistor RM in the vertical direction (Z direction), and at least one oxide thin film 134C, each of which is between two adjacent ones of the plurality of SiCN films 132C. FIG. 5 illustrates an example in which the insulating resistor protective structure PSR includes three SiCN films 132C sequentially stacked in the vertical direction (Z direction) and two oxide thin films 134C, each of which is between two adjacent ones of the three SiCN films 132C, but the inventive concept is not limited to the example shown in FIG. 5. The number of SiCN films 132C and the number of oxide thin films 134C in the insulating resistor protective structure PSR may be variously selected as needed. In embodiments, the oxide thin film 134C may include a silicon oxide film. As used herein, the SiCN film 132C may also be referred to as a third SiCN film, and the oxide thin film 134C may also be referred to as a third oxide thin film.

Detailed configurations of the plurality of SiCN films 132C and a plurality of oxide thin films 134C in the insulating resistor protective structure PSR are respectively and substantially the same as those of the plurality of SiCN films 132A and the plurality of oxide thin films 134A in the insulating protective structure PS, which have been described with reference to FIG. 2. At least a portion of the insulating resistor protective structure PSR may have the same configuration as a portion of a lower insulating protective structure PSL or a portion of the upper insulating protective structure PSU.

A top surface of the insulating resistor protective structure PSR may be covered by a register capping insulating film PSCR. A bottom surface of the register capping insulating film PSCR may be in contact with the top surface of the insulating resistor protective structure PSR. The register capping insulating film PSCR may include a silicon oxide film, an aluminum oxide film, or a combination thereof.

The thin film resistor RM may cover only a portion of the top surface of the upper capping insulating film PSCU. A portion of the top surface of the upper capping insulating film PSCU, which is not covered by the thin film resistor RM, a sidewall of the thin film resistor RM, a sidewall of the insulating resistor protective structure PSR, a sidewall of the register capping insulating film PSCR, and the top surface of the register capping insulating film PSCR may be covered by an interlayer insulating film 260. A constituent material of the interlayer insulating film 260 may substantially be the same as a constituent material of the interlayer insulating film 160, which has been described with reference to FIG. 4.

The IC device 200 may include first and second contact plugs 270A and 270B on the plurality of upper metal wiring layers 150. The first contact plug 270A may pass through the interlayer insulating film 260, the register capping insulating film PSCR, and the insulating resistor protective structure PSR in the vertical direction (Z direction) and contact the thin film resistor RM. The second contact plug 270B may be spaced apart from the thin film resistor RM in a lateral direction (e.g., the first lateral direction (X direction)). The second contact plug 270B may pass through the interlayer insulating film 260, the upper capping insulating film PSCU, and the upper insulating protective structure PSU in the vertical direction (Z direction) and be connected to a selected one of the plurality of upper metal wiring layers 150. The second contact plug 270B may be spaced apart from each of the thin film resistor RM and the first contact plug 270A in a lateral direction with the interlayer insulating film 260 therebetween.

In embodiments, the thin film resistor RM may control the flow of charges and/or a resistance value in a multilayered wiring structure (e.g., a multilayered wiring structure including a plurality of lower metal wiring layers 130, the plurality of conductive contact plugs VC, the plurality of upper metal wiring layers 150, and the first and second contact plugs 270A and 270B) included in the IC device 200, and control the amount of current by using the thin film resistor RM.

In other embodiments, the thin film resistor RM may serve as a dummy wiring layer, which may reduce a difference in the density of a metal wiring structure included in the IC device 200 and prevent the formation of steps in a chemical mechanical polishing (CMP) process performed during the manufacture of the IC device 200.

Referring to FIG. 6, the IC device 200A may substantially have the same configuration as the IC device 200 described with reference to FIG. 5. However, the IC device 200A may further include a first upper insulating protective structure PSU1 covering a top surface of each of the plurality of upper metal wiring layers 150 and the upper insulating film 140, a second upper insulating protective structure PSU2 covering a top surface of each of the first and second contact plugs 270A and 270B and the interlayer insulating film 260, an interlayer insulating film 280 covering the second upper insulating protective structure PSU2, and an upper capping insulating film PSCU2 between the second upper insulating protective structure PSU2 and the interlayer insulating film 280.

A bottom surface of the upper capping insulating film PSCU2 may be in contact with a top surface of the second upper insulating protective structure PSU2, and a top surface of the upper capping insulating film PSCU2 may be in contact with a bottom surface of the interlayer insulating film 280. A detailed configuration of the upper capping insulating film PSCU2 is the same as that of the upper capping insulating film PSCU, which has been described with reference to FIG. 4. A constituent material of the interlayer insulating film 280 may substantially be the same as a constituent material of each of the first interlayer insulating film 114 and the second interlayer insulating film 124, which has been described with reference to FIG. 2. For example, the interlayer insulating film 280 may have a low-k dielectric film (e.g., a SiOC film or a SiCOH film) having a low dielectric constant of about 2.2 to about 3.0.

The first upper insulating protective structure PSU1 may have the same configuration as the upper insulating protective structure PSU described with reference to FIG. 5. The first upper insulating protective structure PSU1 may include a plurality of SiCN films 132B, which are sequentially stacked on the top surface of each of the plurality of upper metal wiring layers 150 and the upper insulating film 140 in the vertical direction (Z direction), and at least one oxide thin film 134B, each of which is between two adjacent ones of the plurality of SiCN films 132B.

The second upper insulating protective structure PSU2 may substantially have the same configuration as the upper insulating protective structure PSU described with reference to FIG. 5. The second upper insulating protective structure PSU2 may include a plurality of SiCN films 132D, which are sequentially stacked on the top surface of each of the first and second contact plugs 270A and 270B and the interlayer insulating film 260 in the vertical direction (Z direction), and at least one oxide thin film 134D, each of which is between two adjacent ones of the plurality of SiCN films 132D. FIG. 6 illustrates an example in which the second upper insulating protective structure PSU2 includes three SiCN films 132D sequentially stacked in the vertical direction (Z direction) and two oxide thin films 134D, each of which is between two adjacent ones of the three SiCN films 132D, but the inventive concept is not limited to the example shown in FIG. 6. The number of the SiCN films 132D and the number of oxide thin films 134D in the second upper insulating protective structure PSU2 may be variously selected as needed. In embodiments, the oxide thin film 134D may include a silicon oxide film. As used herein, the SiCN film 132D may also be referred to as a fourth SiCN film, and the oxide thin film 134D may also be referred to as a fourth oxide thin film. Detailed configurations of the plurality of SiCN films 132D and a plurality of oxide thin films 134D in the second upper insulating protective structure PSU2 are respectively and substantially the same as those of the plurality of SiCN films 132A and the plurality of oxide thin films 134A in the insulating protective structure PS, which have been described with reference to FIG. 2.

A bottom surface of the second upper insulating protective structure PSU2 may be in contact with the top surface of each of the first and second contact plugs 270A and 270B and the interlayer insulating film 260, and the top surface of the second upper insulating protective structure PSU2 may be in contact with the bottom surface of the upper capping insulating film PSCU2.

In the IC devices 100A, 100B, 200, and 200A described with reference to FIGS. 3 to 6, similar to the IC device 100 described with reference to FIGS. 1 and 2, each of the insulating protective structure PS, the lower insulating protective structure PSL, the upper insulating protective structure PSU, the first upper insulating protective structure PSU1, and the second upper insulating protective structure PSU2 may include the plurality of SiCN films 132A, 132B, 132C, or 132D, which are sequentially stacked in the vertical direction (Z direction), and at least one oxide thin film 134A, 134B, 134C, or 134D, each of which is between two adjacent ones of the plurality of SiCN films 132A, 132B, 132C, or 132D. As described above, an etching process of forming a subsequent wiring structure may be performed while a top surface of an underlying metal wiring layer is covered by the insulating protective structure PS, the lower insulating protective structure PSL, the upper insulating protective structure PSU, the first upper insulating protective structure PSU1, and/or the second upper insulating protective structure PSU2 in which the plurality of SiCN films 132A, 132B, 132C, or 132D and the at least one oxide thin film 134A, 134B, 134C, or 134D, which include different materials from each other, are alternately stacked in the vertical direction (Z direction), Therefore, the underlying metal wiring layer may be protected by the insulating protective structure PS), the lower insulating protective structure PSL), the upper insulating protective structure PSU), the first upper insulating protective structure PSU1), and/or the second upper insulating protective structure PSU2 and prevented from being damaged, and the electrical reliability of a multilayered wiring structure may improve. Therefore, the reliability of the IC devices 100A, 100B, 200, and 200A may improve.

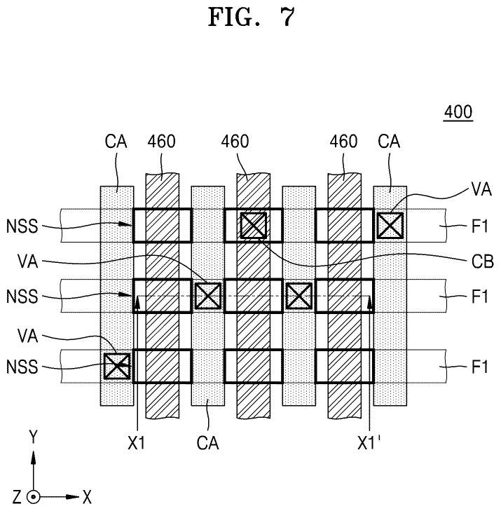

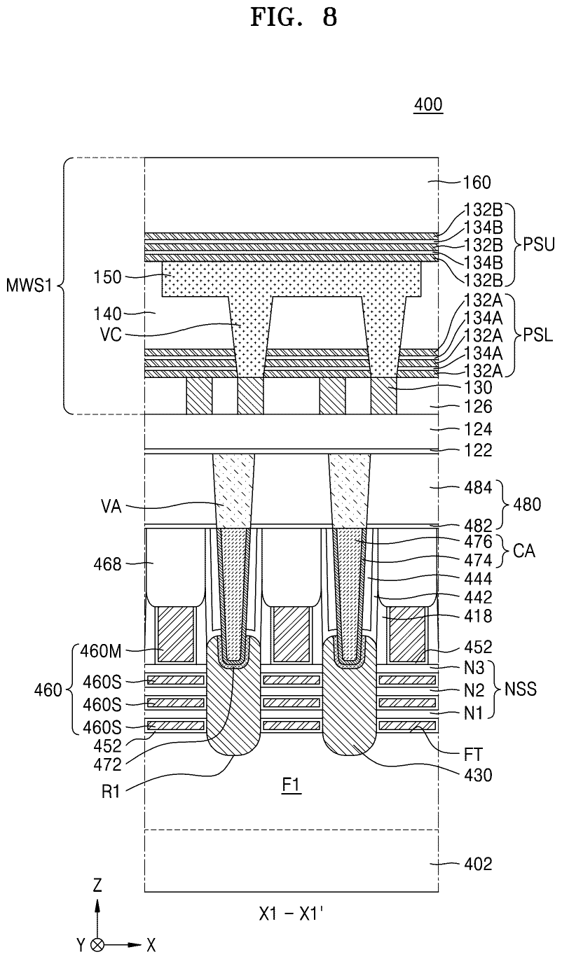

FIG. 7 is a schematic plan layout diagram of an IC device 400 according to embodiments. FIG. 8 is a schematic cross-sectional view taken along line X1-X1′ of FIG. 7. The IC device 400 including a field-effect transistor (FET) having a gate-all-around structure including an active region of a nanowire or nanosheet type and a gate surrounding (i.e., extending around) the active region is described with reference to FIGS. 7 and 8. In FIGS. 7 and 8, the same reference numerals are used to denote the same elements as in FIGS. 1 to 3, and detailed descriptions thereof are omitted.

Referring to FIGS. 7 and 8, the IC device 400 may include a plurality of fin-type active regions F1 and a plurality of nanosheet stacks NSS. The plurality of fin-type active regions F1 may protrude (i.e., extend vertically upward) from a substrate 402 and extend longitudinally in a first lateral direction (X direction) parallel to an upper surface of the substrate 402. The plurality of nanosheet stacks NSS may be spaced apart upwardly from the plurality of fin-type active regions F1 in a vertical direction (Z direction), perpendicular to the upper surface of the substrate 402, and face fin top surfaces FT of the plurality of fin-type active regions F1. As used herein, the term “nanosheet” refers to a conductive structure having a cross-section that is substantially perpendicular to a direction in which current flows. The nanosheet may be interpreted as including a nanowire.

A trench defining the plurality of fin-type active regions F1 may be formed in the substrate 402. The trench may be filled by a device isolation film. The term “filled” (or “fills,” or like terms), as may be used herein, is intended to refer broadly to either completely filling a defined space (e.g., the trench) or partially filling the defined space; that is, the defined space need not be entirely filled but may, for example, be partially filled or have voids or other spaces throughout. The substrate 402 may include a semiconductor, such as silicon (Si) or germanium (Ge), or a compound semiconductor, such as silicon germanium (SiGe), silicon carbide (SIC), gallium arsenide (GaAs), indium arsenide (InAs), indium gallium arsenide (InGaAs), or indium phosphide (InP), although embodiments are not limited thereto. The substrate 402 may include a conductive region, for example, a doped well or a doped structure. The device isolation film may include an oxide film, a nitride film, or a combination thereof.

A plurality of gate lines 460 may be on the plurality of fin-type active regions F1. Each of the plurality of gate lines 460 may extend longitudinally in a second lateral direction (Y direction) parallel to the upper surface of the substrate 402 and intersecting the first lateral direction (X direction).

A plurality of nanosheet stacks NSS may be respectively on the fin top surfaces FT of the plurality of fin-type active regions F1 in regions where the plurality of fin-type active regions F1 intersect the plurality of gate lines 460. Each of the plurality of nanosheet stacks NSS may include at least one nanosheet facing the fin top surface FT of the fin-type active region F1 at a position apart from the fin top surface FT of the fin-type active region F1 in the vertical direction (Z direction).

In embodiments, each of the plurality of nanosheet stacks NSS may include a first nanosheet N1, a second nanosheet N2, and a third nanosheet N3, which overlap each other in the vertical direction (Z direction) on the fin-type active region F1. Each of the plurality of gate lines 460 may surround the first nanosheet N1, the second nanosheet N2, and the third nanosheet N3, which overlap each other in the vertical direction (Z direction) and are included in the nanosheet stack NSS.

Each of the plurality of gate lines 460 may include a main gate portion 460M and a plurality of sub-gate portions 460S. The main gate portion 460M may extend longitudinally in the second lateral direction (Y direction), while covering a top surface of the nanosheet stack NSS. The plurality of sub-gate portions 460S may be integrally connected to the main gate portion 460M and respectively located between the first nanosheet N1, the second nanosheet N2, and the third nanosheet N3 and between the first nanosheet N1 and the fin-type active region F1. In the vertical direction (Z direction), a thickness of each of the plurality of sub-gate portions 460S may be less than a thickness of the main gate portion 460M.

A plurality of recesses R1 may be formed in the fin-type active region F1. A lowermost surface of each of the plurality of recesses R1 may be at a lower vertical level than the fin top surface FT of the fin-type active region F1, relative to a bottom surface of the substrate 402 as a reference. The plurality of source/drain regions 430 may be inside the plurality of recesses R1. Each of the plurality of source/drain regions 430 may be adjacent to at least one gate line 460 selected from the plurality of gate lines 460. Each of the plurality of source/drain regions 430 may be in contact with the first nanosheet N1, the second nanosheet N2, and the third nanosheet N3, which are included in the nanosheet stack NSS adjacent thereto.

Each of the plurality of gate lines 460 may include a metal, a metal nitride, a metal carbide, or a combination thereof. The metal may be selected from titanium (Ti), tungsten (W), ruthenium (Ru), niobium (Nb), molybdenum (Mo), hafnium (Hf), nickel (Ni), cobalt (Co), platinum (Pt), ytterbium (Yb), terbium (Tb), dysprosium (Dy), erbium (Er), and palladium (Pd). The metal nitride may be selected from TiN and TaN. The metal carbide may include titanium aluminum carbide (TiAlC). However, a constituent material of the plurality of gate lines 460 is not limited to the examples described above. Each of the plurality of gate lines 460 may further include a gap-fill metal film. The gap-fill metal film may include a tungsten (W) film and an aluminum (Al) film. In embodiments, each of the plurality of gate lines 460 may include a TiN film, a stack structure of TiAlC/TiN/W, a stack structure of TiN/TaN/TiAlC/TiN/W, or a stack structure of TiN/TaN/TiN/TiAlC/TiN/W, without being limited thereto.

A gate dielectric film 452 may be between the nanosheet stack NSS and the gate line 460. In embodiments, the gate dielectric film 452 may include a stack structure of an interface dielectric film and a high-k dielectric film. In one or more embodiments, the interface dielectric film may include a low-k dielectric material film having a dielectric constant of about 9 or lower, for example, a silicon oxide film, a silicon oxynitride film, or a combination thereof. In some embodiments, the interface dielectric film may be omitted. The high-k dielectric film may include a material having a higher dielectric constant than a silicon oxide film. For example, the high-k dielectric film may have a dielectric constant of about 10 to about 25. The high-k dielectric film may include hafnium oxide, without being limited thereto.

Both sidewalls of the gate line 460 may be covered by insulating spacers 418. The insulating spacers 418 may cover both sidewalls of the main gate portion 460M on a top surface of each of the plurality of nanosheet stacks NSS. The insulating spacers 418 may be spaced apart from the gate line 460 with the gate dielectric film 452 therebetween. The insulating spacers 418 may include, for example, silicon nitride, silicon oxide, silicon carbonitride (SiCN), silicon boronitride (SiBN), silicon oxynitride (SiON), silicon oxycarbonitride (SiOCN), silicon boron carbonitride (SiBCN), silicon oxycarbide (SiOC), or a combination thereof.

A top surface of each of the gate dielectric film 452, the gate line 460, and the insulating spacers 418 may be covered by a capping insulating pattern 468. The capping insulating pattern 468 may contact a top surface of each of the gate dielectric film 452, the gate line 460, and the insulating spacers 418. The capping insulating pattern 468 may include a silicon nitride film.

Both sidewalls of each of the plurality of sub-gate portions 460S may be apart from the source/drain region 430 with the gate dielectric film 452 therebetween. The gate dielectric film 452 may be between the sub-gate portion 460S included in the gate line 460 and each of the first nanosheet N1, the second nanosheet N2, and the third nanosheet N3 and between the sub-gate portion 460S included in the gate line 460 and the source/drain region 430.

A plurality of nanosheet transistors may be formed in portions where the plurality of fin-type active regions F1 intersect the plurality of gate lines 460 on the substrate 402. Each of the first nanosheet N1, the second nanosheet N2, and the third nanosheet N3 included in the nanosheet stack NSS may have a channel region. In embodiments, each of the first nanosheet N1, the second nanosheet N2, and the third nanosheet N3 included in the nanosheet stack NSS may include a silicon (Si) layer, a silicon germanium (SiGe) layer, or a combination thereof.

A metal silicide film 472 may be formed on a top surface of each of the plurality of source/drain regions 430. The metal silicide film 472 may include a metal, which includes Ti, W, Ru, Nb, Mo, Hf, Ni, Co, Pt, Yb, Tb, Dy, Er, or Pd. For example, the metal silicide film 472 may include titanium silicide, without being limited thereto.

An insulating liner 442 and an inter-gate dielectric film 444 may be sequentially on the plurality of source/drain regions 430 and a plurality of metal silicide films 472. In embodiments, the insulating liner 442 may include silicon nitride (SiN), SiCN, SiBN, SiON, SiOCN, SiBCN, or a combination thereof, and the inter-gate dielectric film 444 may include a silicon oxide film, without being limited thereto.

A plurality of source/drain contacts CA may be on the plurality of source/drain regions 430. Each of the plurality of source/drain contacts CA may pass through the inter-gate dielectric film 444 and the insulating liner 442 in the vertical direction (Z direction) and contact the metal silicide film 472. Each of the plurality of source/drain contacts CA may be electrically connectable to the source/drain region 430 through the metal silicide film 472. Each of the plurality of source/drain contacts CA may be apart from the main gate portion 460M with the insulating spacers 418 therebetween in the first lateral direction (X direction).

Each of the plurality of source/drain contacts CA may include a conductive barrier film 474 and a contact plug 476, which are sequentially stacked on the metal silicide film 472. The conductive barrier film 474 may surround and contact a bottom surface and a sidewall of the contact plug 476. In one or more embodiments, the conductive barrier film 474 may include a metal or a metal nitride. For example, the conductive barrier film 474 may include titanium (Ti), tantalum (Ta), tungsten (W), titanium nitride (TiN), tantalum nitride (TaN), tungsten nitride (WN), tungsten carbonitride (WCN), titanium silicon nitride (TiSiN), tantalum silicon nitride (TaSiN), tungsten silicon nitride (WSiN), or a combination thereof. The contact plug 476 may include a metal selected from molybdenum (Mo), copper (Cu), tungsten (W), cobalt (Co), ruthenium (Ru), manganese (Mn), titanium (Ti), tantalum (Ta), aluminum (Al), and a combination thereof.

A lower insulating structure 480 may be on a top surface of each of the plurality of source/drain contacts CA and a plurality of capping insulating patterns 468. The lower insulating structure 480 may include a lower etch stop film 482 and a first interlayer insulating film 484, which are sequentially stacked on the top surface of each of the plurality of capping insulating patterns 468. The lower etch stop film 482 may include, for example, silicon carbide (SiC), silicon nitride (SiN), nitrogen (N)-doped silicon carbide (SiC:N), silicon oxycarbide (SiOC), aluminum nitride (AlN), aluminum oxynitride (AlON), aluminum oxide (AlO), aluminum oxycarbide (AlOC), or a combination thereof. A constituent material of the first interlayer insulating film 484 may substantially be the same as that of the first interlayer insulating film 114 described with reference to FIG. 2.

As shown in FIG. 8, a plurality of source/drain via contacts VA may be respectively on the plurality of source/drain contacts CA. Each of the plurality of source/drain via contacts VA may pass through the lower insulating structure 480 and contact the source/drain contact CA. Each of the plurality of source/drain regions 430 may be electrically connected to the source/drain via contact VA through the metal silicide film 472 and the source/drain contact CA.

As shown in FIG. 7, a gate contact CB may be on the gate line 460. The gate contact CB may pass through the lower insulating structure 480 and the capping insulating pattern 468 in the vertical direction (Z direction) and be connected to the gate line 460.

Each of the plurality of source/drain via contacts VA and the gate contact CB may include a contact plug, which includes molybdenum (Mo), copper (Cu), tungsten (W), cobalt (Co), ruthenium (Ru), manganese (Mn), titanium (Ti), tantalum (Ta), aluminum (Al), a combination thereof, or an alloy thereof, but a constituent material of the contact plug is not limited thereto. In embodiments, each of the plurality of source/drain via contacts VA and the gate contact CB may further include a conductive barrier pattern surrounding a portion of the contact plug. The conductive barrier pattern included in each of the plurality of source/drain via contacts VA and the gate contact CB may include a metal or a metal nitride. For example, the conductive barrier pattern may include Ti, Ta, W, TiN, TaN, WN, WCN, TiSiN, TaSiN, WSiN, or a combination thereof, without being limited thereto.

A second lower etch stop film 122 and a second interlayer insulating film 124 may be sequentially stacked in the vertical direction (Z direction) on each of the lower insulating structure 480, the source/drain via contact VA, and the gate contact CB.

The IC device 400 may include a multilayered wiring structure MWS1 on the second interlayer insulating film 124. The multilayered wiring structure MWS1 may include a lower insulating film 126, a plurality of lower metal wiring layers 130, a lower insulating protective structure PSL, and an upper insulating film 140. In addition, the multilayered wiring structure MWS1 may include a plurality of conductive contact plugs VC, an upper metal wiring layer 150, an upper insulating protective structure PSU, and an interlayer insulating film 160. The plurality of conductive contact plugs VC may pass through the upper insulating film 140 and the lower insulating protective structure PSL in the vertical direction (Z direction). The upper metal wiring layer 150 may be integrally connected to a corresponding one of the plurality of conductive contact plugs VC. The upper insulating protective structure PSU and the interlayer insulating film 160 may be sequentially stacked on a top surface of each of the upper metal wiring layer 150 and the upper insulating film 140. Detailed configurations of the above-described components included in the multilayered wiring structure MWS1 are the same as those described with reference to FIG. 3.

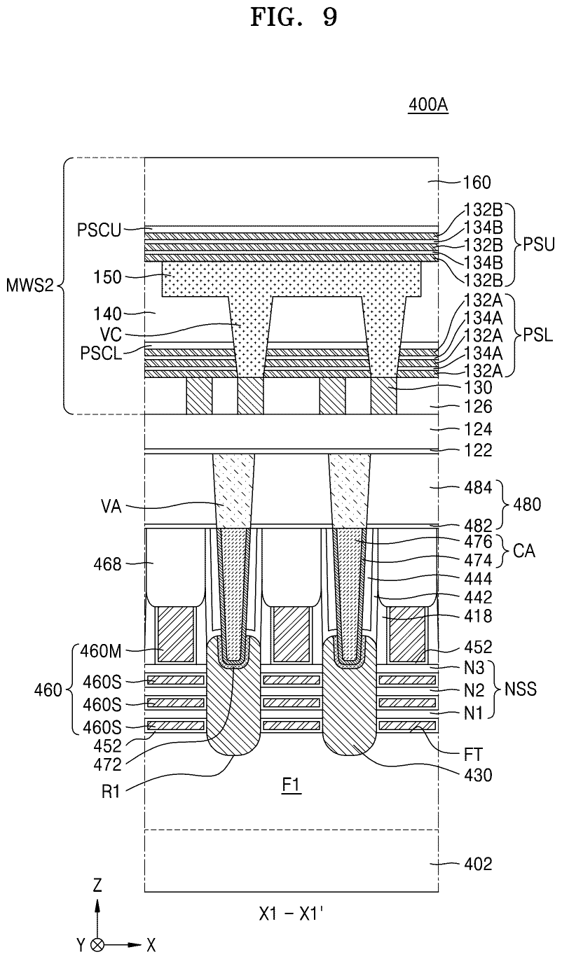

FIG. 9 is a schematic cross-sectional view of an IC device 400A according to embodiments. FIG. 9 illustrates components in a portion corresponding to a cross-section taken along line X1-X1′ of FIG. 7 in the IC device 400A. In FIG. 9, the same reference numerals are used to denote the same elements as in FIGS. 1 to 8, and detailed descriptions thereof are omitted.

Referring to FIG. 9, the IC device 400A may substantially have the same configuration as the IC device 400 described with reference to FIGS. 7 and 8. However, the IC device 400A may include a multilayered wiring structure MWS2 on a second interlayer insulating film 124. The multilayered wiring structure MWS2 may substantially have the same configuration as the multilayered wiring structure MWS1 described with reference to FIG. 8. However, the multilayered wiring structure MWS2 may further include a lower capping insulating film PSCL located between a lower insulating protective structure PSL and an upper insulating film 140 and an upper capping insulating film PSCU located between an upper insulating protective structure PSU and an interlayer insulating film 160. Detailed configurations of the lower capping insulating film PSCL and the upper capping insulating film PSCU are the same as those described with reference to FIG. 4.

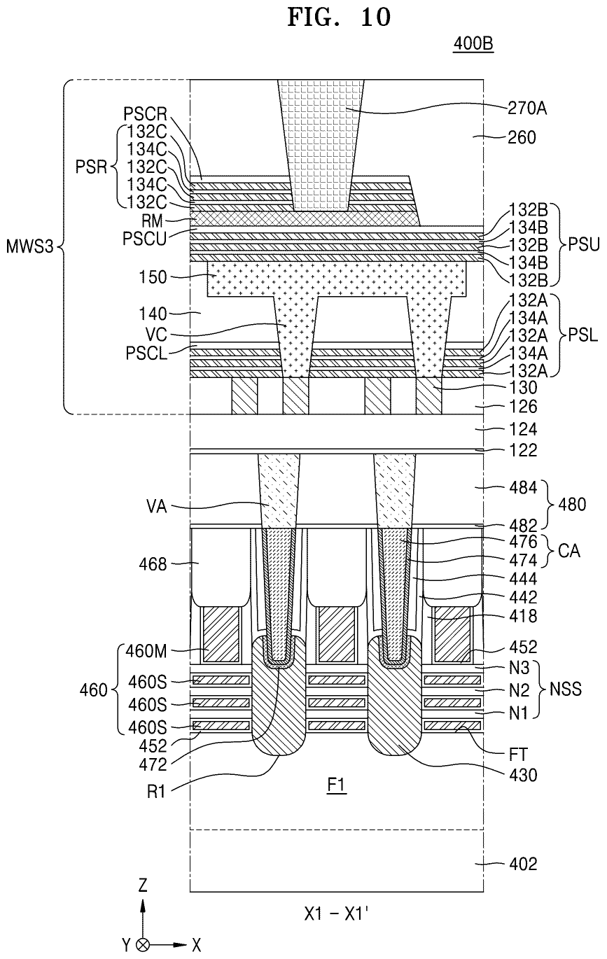

FIG. 10 is a schematic cross-sectional view of an IC device 400B according to embodiments. FIG. 10 illustrates components in a portion corresponding to a cross-section taken along line X1-X1′ of FIG. 7 in the IC device 400. In FIG. 10, the same reference numerals are used to denote the same elements as in FIGS. 1 to 9, and detailed descriptions thereof are omitted.

Referring to FIG. 10, the IC device 400B may substantially have the same configuration as the IC device 400 described with reference to FIGS. 7 and 8. However, the IC device 400B may include a multilayered wiring structure MWS3 on a second interlayer insulating film 124. The multilayered wiring structure MWS3 may substantially have the same configuration as the multilayered wiring structure MWS2 described with reference to FIG. 9. However, the multilayered wiring structure MWS3 may further include a thin film resistor RM on an upper insulating protective structure PSU and an insulating resistor protective structure PSR covering a top surface of the thin film resistor RM.

An upper capping insulating film PSCU may be between the upper insulating protective structure PSU and the thin film resistor RM. The thin film resistor RM may be spaced apart from the upper metal wiring layer 150 in a vertical direction (Z direction) with the upper insulating protective structure PSU and the upper capping insulating film PSCU therebetween. A top surface of the insulating resistor protective structure PSR may be covered by a register capping insulating film PSCR. A portion of a top surface of the upper capping insulating film PSCU, which is not covered by the thin film resistor RM, a sidewall of the thin film resistor RM, a sidewall of the insulating resistor protective structure PSR, a sidewall of the register capping insulating film PSCR, and a top surface of the register capping insulating film PSCR may be covered by an interlayer insulating film 260. The multilayered wiring structure MWS3 may further include a first contact plug 270A on the plurality of upper metal wiring layers 150. The first contact plug 270A may pass through the interlayer insulating film 260, the register capping insulating film PSCR, and the insulating resistor protective structure PSR in the vertical direction (Z direction) and contact the thin film resistor RM. Detailed configurations of the above-described components included in the multilayered wiring structure MWS3 are the same as those described with reference to FIG. 5.

FIGS. 11A to 11H are schematic cross-sectional views depicting a sequence of intermediate processes in an example method of manufacturing an IC device, according to embodiments. FIGS. 11A to 11H each illustrate a cross-sectional configuration of a portion corresponding to a cross-section taken along line X1-X1′ of FIG. 1, according to a process sequence. An example of a method of manufacturing the IC device 100 shown in FIGS. 1 and 2 is described with reference to FIGS. 11A to 11H. In FIGS. 11A to 11H, the same reference numerals are used to denote the same elements as in FIGS. 1 and 2, and detailed descriptions thereof are omitted.

Referring to FIG. 11A, a first lower etch stop film 112 and a first interlayer insulating film 114 may be formed on a substrate 110, and a conductive structure 120 may be formed to pass through the first interlayer insulating film 114 and the first lower etch stop film 112 and be electrically connectable to a conductive region (not shown) of the substrate 110. To form the conductive structure 120, the first interlayer insulating film 114 and the first lower etch stop film 112 may be partially etched to form an opening, and the opening may be filled by conductive materials. The conductive structure 120 may be electrically connected to the conductive region formed in the substrate 110. In some other embodiments, the conductive structure 120 may be a source/drain region of a transistor, a source/drain contact, a via contact, or a gate contact, without being limited thereto.

A second lower etch stop film 122 and a second interlayer insulating film 124 may be formed on the first interlayer insulating film 114. Afterwards, a lower insulating film 126 may be formed on the second interlayer insulating film 124, and a plurality of lower metal wiring layers 130 may be formed to pass through the lower insulating film 126 in a vertical direction (Z direction).

Referring to FIG. 11B, an insulating protective structure PS may be formed on the lower insulating film 126 and the plurality of lower metal wiring layers 130.

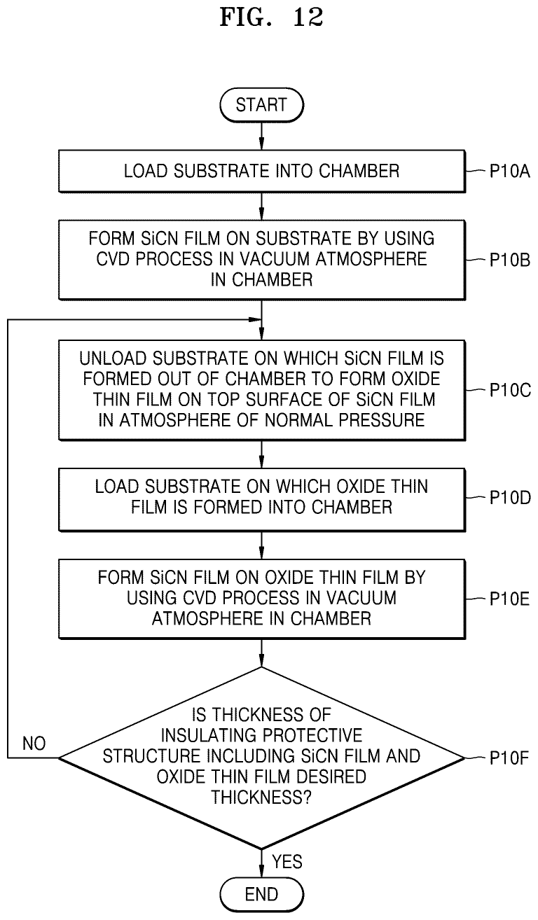

FIG. 12 is a flowchart of a method of forming the insulating protective structure PS according to the process described with reference to FIG. 11B.

Referring to FIGS. 11B and 12, in operation P10A, the substrate 110 in which the resultant structure on which the processes described with reference to FIG. 11A were performed is formed may be loaded into a chamber. The chamber may be a chamber for performing a chemical vapor deposition (CVD) process, for example, a plasma-enhanced CVD (PECVD) process.

In operation P10B of FIG. 12, a SiCN film 132A may be formed on a top surface of each of the lower insulating film 126 and the plurality of lower metal wiring layers 130, which are exposed in the resultant structure of FIG. 11, by using a CVD process in a vacuum atmosphere in the chamber. The SiCN film 132A may be formed by using a PECVD process.

In embodiments, after process gases required to form the SiCN film 132A are supplied into the chamber to form the SiCN film 132A, the supplied gases may be activated into plasma inside the chamber. The process gases may include, for example, a silicon-containing precursor, a carbon-containing precursor, and a nitrogen-containing precursor. For example, trisilylamine, monomethyl silane, dimethyl silane, trimethyl silane, tetramethyl silane, (dimethylamino)trimethylsilane, (dimethylamino)tricthylsilane, hexamethylcyclotrisilazane, or N,N′-disilyltrisilazane may be used as the silicon-containing precursor, without being limited thereto. Methane (CH₄), acetylene (C₂H₂), ethylene (C₂H₄), propylene (C₃H₆), butane (C₄H₁₀), cyclohexane (C₆H₁₂), benzene (C₆H₆), or toluene (C₇H₈) may be used as the carbon-containing precursor, without being limited thereto. Ammonia, nitrogen (N₂) gas, or a combination thereof may be used as the nitrogen-containing precursor, without being limited thereto. The process gases may be supplied along with an inert gas (e.g., helium or argon) into the chamber. During the formation of the SiCN film 132A, the inside of the chamber may be maintained in an atmosphere of a pressure of about 4 Torr to about 60 Torr (e.g., about 8 Torr to about 30 Torr).

In operation P10C of FIG. 12, the substrate 110 on which the SiCN film 132A is formed may be unloaded out of the chamber, and an oxide thin film 134A may be formed on a top surface of the SiCN film 132A in an atmosphere of normal pressure of about 760 Torr. In embodiments, the oxide thin film 134A may include a film obtained by natural oxidation of the top surface of the SiCN film 132A in the atmosphere.

In operation P10D of FIG. 12, the substrate 110 on which the oxide thin film 134A is formed according to operation P10C may be loaded into a chamber.

In embodiments, the chamber used in operation P10C may be the same as the chamber used in operation P10A. In other embodiments, the chamber used in operation P10C may be a chamber, which is selected from a plurality of chambers that constitute one cluster tool along with the chamber used in operation P10A and is different from the chamber used in operation P10A.

In operation P10E of FIG. 12, the SiCN film 132A may be formed on the oxide thin film 134A by using a CVD process in a vacuum atmosphere in the chamber in which the substrate 110 on which the oxide thin film 134A is formed is loaded according to operation P10D. A detailed process of forming the SiCN film 132A is the same as that described in operation P10B.

In operation P10F of FIG. 12, it may be determined whether a thickness of an insulating protective structure including the plurality of SiCN films 132A and the oxide thin film 134A formed on the substrate 110 is a desired thickness. If it is determined that the thickness of the insulating protective structure is not the desired thickness, the above-described processes P10C, P10D, and P10E may be sequentially performed.

In operation P10F of FIG. 12, when the thickness of the insulating protective structure including the plurality of SiCN films 132A and the oxide thin film 134A formed on the insulating protective structure is the desired thickness, the process of forming the insulating protective structure PS, which has been described with reference to FIG. 11B, may be ended.

Referring to FIG. 11C, in the resultant structure of FIG. 11B, an upper insulating film 140 may be formed to cover a top surface of the insulating protective structure PS.

Referring to FIG. 11D, a first hard mask pattern HM1 may be formed on the upper insulating film 140. The first hard mask pattern HM1 may have a plurality of openings H1 having shapes corresponding to planar shapes of the plurality of upper metal wiring layers (refer to 150 in FIGS. 1 and 2). A top surface of the upper insulating film 140 may be exposed through the plurality of openings H1 formed in the first hard mask pattern HM1.

The first hard mask pattern HM1 may include a single mask pattern including a metal-containing film or a multiple mask pattern including a combination of a metal-containing film and a silicon oxide film. The metal-containing film may include a titanium nitride (TiN) film or a tungsten (W)-doped carbon film, without being limited thereto.

Referring to FIG. 11E, a second hard mask pattern HM2 may be formed on the resultant structure of FIG. 11D. The second hard mask pattern HM2 may be formed by using a photolithography process.

The second hard mask pattern HM2 may have a plurality of openings H2. Positions of the plurality of openings H2 may correspond to positions of the plurality of conductive contact plugs VC shown in FIG. 2. The top surface of the upper insulating film 140 may be exposed through the plurality of openings H2 formed in the second hard mask pattern HM2. The second hard mask pattern HM2 may include a spin-on mask (SOH), SiON, or a combination thereof, without being limited thereto.

Referring to FIG. 11F, in the resultant structure of FIG. 11E, the upper insulating film 140 may be etched by a partial thickness (from an upper surface of the upper insulating film 140) by using the first hard mask pattern HM1 and the second hard mask pattern HM2 as etch masks, and thus, a plurality of upper via holes PVH may be formed in the upper insulating film 140. Thereafter, the second hard mask pattern HM2 may be removed.

In embodiments, the formation of the plurality of upper via holes PVH may be performed by using a plasma-enhanced atomic layer etching (PEALE) process. In embodiments, the process of etching the upper insulating film 140 to form the plurality of upper via holes PVH may include an operation (operation A) of supplying an etch gas together with argon (Ar) gas into a reaction chamber, an operation (operation B) of purging the inside of the reaction chamber into which the etch gas is supplied by using the Ar gas, an operation (operation C) of supplying a reactive gas together with Ar gas into the reaction chamber, and an operation (operation D) of purging the inside of the reaction chamber into which the reactive gas is supplied. In the operation A, the etch gas may include a fluorocarbon compound. For example, the etch gas may include CHF₃, CH₂F₂, CH₃F, CF₄, C₂F₆, C₄F₈, C₄F₆, or a combination thereof, without being limited thereto. In the operation C, the reactive gas may include O₂, CO₂, N₂O, or a combination thereof, without being limited thereto.

In the operation A, pulsed radio-frequency (RF) power may be applied to the reaction chamber to generate reactive species of the Ar gas and bring a surface of the upper insulating film 140 on which the etch gas is chemisorbed, into contact with the reactive species such that the upper insulating film 140 is etched. In the operation C, to increase an etch rate of the upper insulating film 140, oxygen plasma may be generated by applying the pulsed RF to the reaction chamber. As a result, the upper insulating film 140 may be sputtered by using positively (+) charged Art. A single PEALE cycle including the operations (A), (B), (C), and (D) described above may be repeated a plurality of times.

After the plurality of upper via holes PVH are formed, a bottom surface of each of the plurality of upper via holes PVH may be spaced apart from the top surface of the insulating protective structure PS in a vertical direction (Z direction).

Referring to FIG. 11G, in the resultant structure of FIG. 11F, the upper insulating film 140, which is exposed, may be etched by using the first hard mask pattern HM1 as an etch mask, and an upper wiring trench LH and a plurality of via holes VH may be formed. The upper wiring trench LH may be connected to the via hole VH corresponding thereto. To form the plurality of via holes VH, processes similar to the processes of forming the plurality of upper via holes PVH, which have been described with reference to FIG. 11F, may be performed.

The plurality of via holes VH may be formed to pass through the upper insulating film 140 and the insulating protective structure PS in the vertical direction (Z direction). The top surface of the lower metal wiring layer 130 may be exposed at the bottom of each of the plurality of via holes VH, and the upper insulating film 140 and the insulating protective structure PS may be exposed at a sidewall of each of the plurality of via holes VH.

Referring to FIG. 11H, in the resultant structure of FIG. 11G, a metal-containing conductive layer may be formed to fill the plurality of via holes VH and the upper wiring trench LH. Thereafter, the metal-containing conductive layer may be planarized by using a CMP process to expose the top surface of the upper insulating film 140, and thus, a plurality of conductive contact plugs VC and an upper metal wiring layer 150 may be formed.

The metal-containing conductive layer may include a metal plug and a conductive barrier film surrounding a sidewall and a bottom surface of the metal plug. The metal plug may include Cu, W, Mo, Ru, Co, Al, or a combination thereof. For example, the metal plug may include Cu. The conductive barrier film may include a TiN film, a TaN film, a Co film, or a combination thereof. For example, when the metal plug includes Cu, the conductive barrier film may include a multilayered structure including a TaN film and a Co film, without being limited thereto.

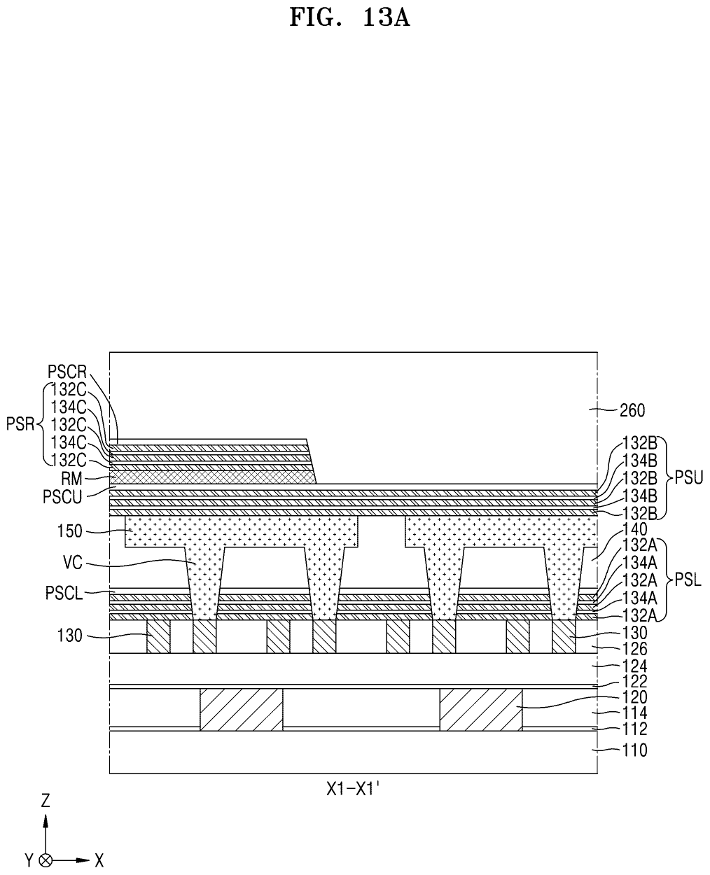

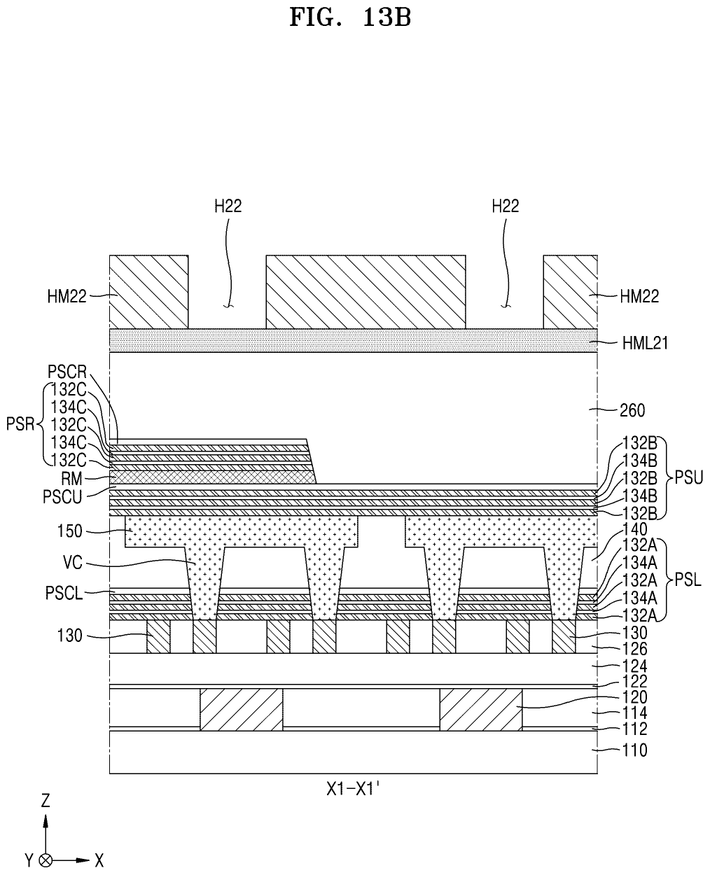

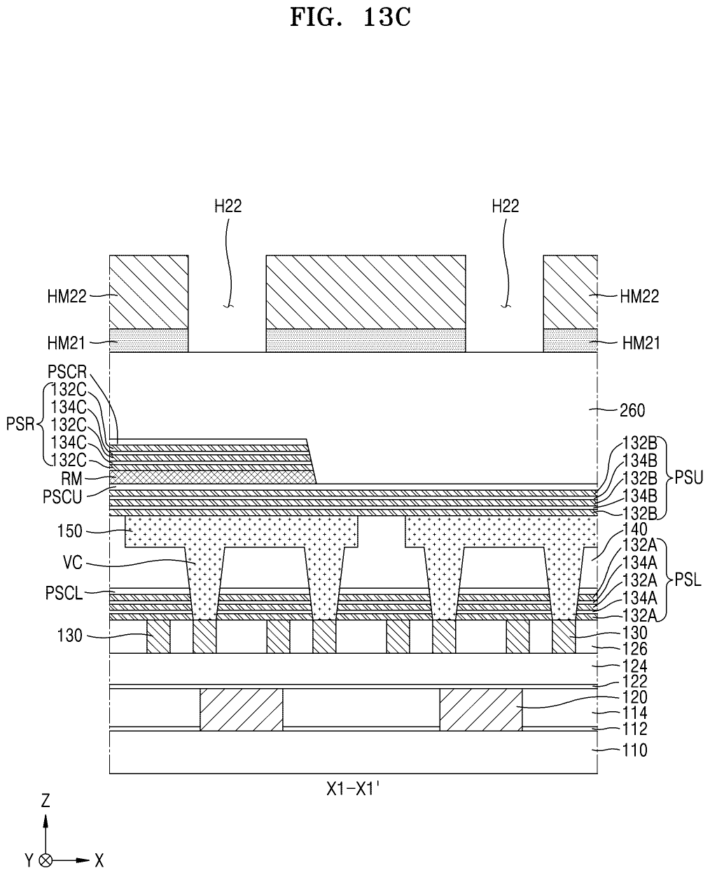

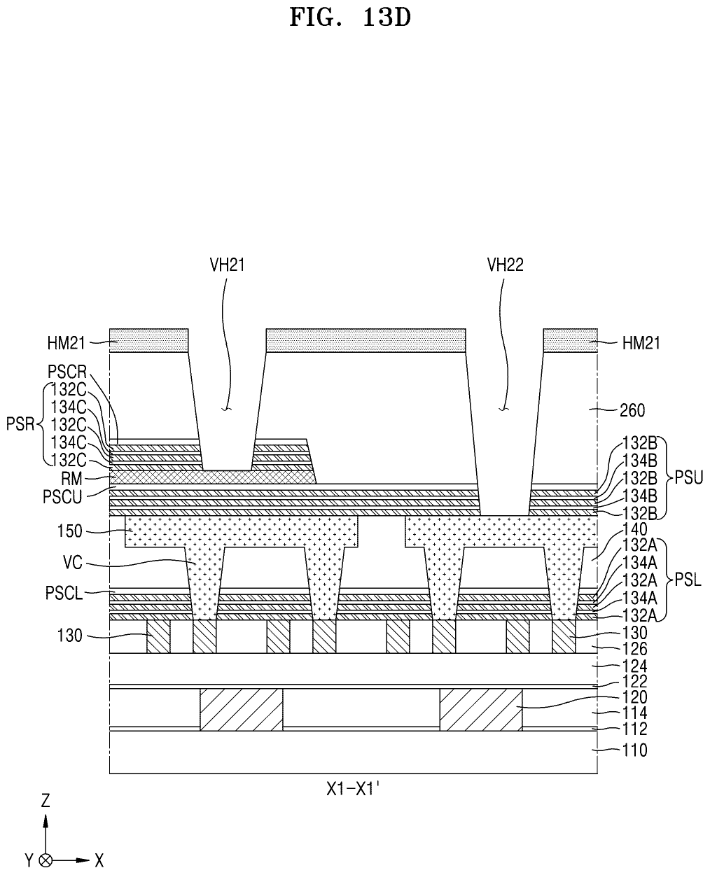

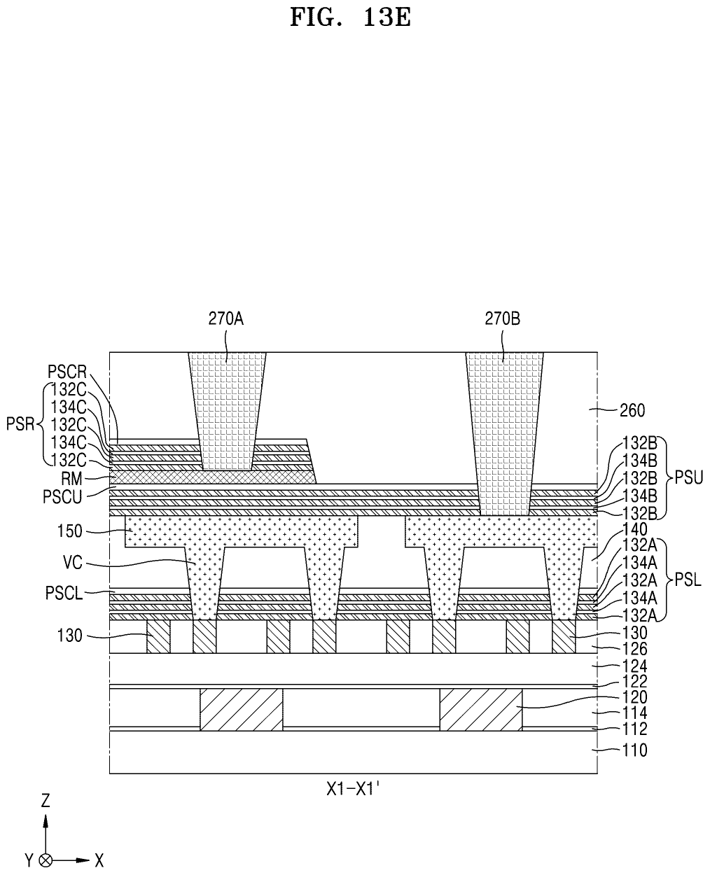

FIGS. 13A to 13E are schematic cross-sectional views depicting a sequence of intermediate processes in an example method of manufacturing an IC device, according to embodiments. An example of a method of manufacturing the IC device 200 shown in FIG. 5 is described with reference to FIGS. 13A to 13E. In FIGS. 13A to 13E, the same reference numerals are used to denote the same elements as in FIGS. 1 to 11H, and detailed descriptions thereof are omitted.

Referring to FIG. 13A, by using a method similar to that described with reference to FIGS. 11A to 11H, a structure in which a plurality of upper metal wiring layers 150 spaced apart from each other in a first lateral direction (X direction) may be formed on a substrate 110. However, a lower insulating protective structure PSL may be formed in the same manner as when the insulating protective structure PS is formed in the process described with reference to FIG. 11B. Thereafter, before an upper insulating film 140 is formed in the process described with reference to FIG. 11C, a lower capping insulating film PSCL may be formed to cover a top surface of the lower insulating protective structure PSL. The upper insulating film 140 may be formed to cover a top surface of the lower capping insulating film PSCL.

Afterwards, an upper capping insulating film PSCU may be formed to cover a top surface of the upper insulating protective structure PSU, and a thin film resistor RM, an insulating resistor protective structure PSR, and a register capping insulating film PSCR may be sequentially formed on the upper capping insulating film PSCU. To form the insulating resistor protective structure PSR, the same processes as when the insulating protective structure PS is formed as described with reference to FIGS. 11B and 12 may be performed. Thereafter, a portion of each of the thin film resistor RM, the insulating resistor protective structure PSR, and the register capping insulating film PSCR may be removed by using an etching process such that the thin film resistor RM, the insulating resistor protective structure PSR, and the register capping insulating film PSCR remain only on desired areas of the substrate 110. As a result, a top surface of the upper capping insulating film PSCU may be exposed around each of the thin film resistor RM, the insulating resistor protective structure PSR, and the register capping insulating film PSCR that remain on the substrate 110. Afterwards, an interlayer insulating film 260 may be formed to cover the thin film resistor RM, the insulating resistor protective structure PSR, and the register capping insulating film PSCR, which remain on the substrate 110, and the top surface of the upper capping insulating film PSCU.

Referring to FIG. 13B, a first hard mask layer HML21 may be formed on the resultant structure of FIG. 13A, and a second hard mask pattern HM22 may be formed on the first hard mask layer HML21. The second hard mask pattern HM22 may have a plurality of openings H22 exposing a top surface of the first hard mask layer HML21.

In some embodiments, the first hard mask layer HML21 may include a metal-containing film. For example, the first hard mask layer HML21 may include a tantalum nitride (TaN) film, a titanium nitride (TiN) film, or a combination thereof, without being limited thereto. The second hard mask pattern HM22 may include a SiON film, without being limited thereto. The second hard mask pattern HM22 may be formed by using a photolithography process.

Referring to FIG. 13C, in the resultant structure of FIG. 13B, the first hard mask layer HML21 may be etched by using the second hard mask pattern HM22 as an etch mask to form a first hard mask pattern HM21. A top surface of the interlayer insulating film 260 may be exposed through the first hard mask pattern HM21. During the formation of the first hard mask pattern HM21, at least a portion of the second hard mask pattern HM22 on the first hard mask pattern HM21 may be consumed.

Referring to FIG. 13D, in the resultant structure of FIG. 13C, the interlayer insulating film 260, the register capping insulating film PSCR, and the insulating resistor protective structure PSR may be etched by using the first hard mask pattern HM21 as an etch mask. Thus, a first via hole VH21 may be formed to pass through each of the interlayer insulating film 260, the register capping insulating film PSCR, and the insulating resistor protective structure PSR in the vertical direction (Z direction). Simultaneously, by using the first hard mask pattern HM21 as an etch mask, a second via hole VH22 may be formed to pass through the interlayer insulating film 260, the upper capping insulating film PSCU, and the upper insulating protective structure PSU in the vertical direction (Z direction). A top surface of the thin film resistor RM may be exposed at the bottom of the first via hole VH21, and a top surface of the upper metal wiring layer 150 may be exposed at the bottom of the second via hole VH22.

Referring to FIG. 13E, in the resultant structure of FIG. 13D, the first hard mask pattern HM21 may be removed to expose a top surface of the interlayer insulating film 260. Afterwards, a metal-containing conductive layer may be formed to fill the first via hole VH21 and the second via hole VH22. Subsequently, the metal-containing conductive layer may be planarized by using a CMP process to expose the top surface of the interlayer insulating film 260, and thus, first and second contact plugs 270A and 270B may be formed.

Although the methods of manufacturing the IC device 100 shown in FIGS. 1 and 2 and the IC device 200 shown in FIG. 5 have been described with reference to FIGS. 11A to 13E, it will be understood that the IC devices 100A, 100B, 200A, 400, 400A, and 400B shown in FIGS. 3, 4, and 6 to 10 and IC devices having variously changed structures may be manufactured by applying various modifications and changes to the processes described with reference to FIGS. 11A to 13E within the scope of the inventive concept.

While the inventive concept has been particularly shown and described with reference to embodiments thereof, it will be understood that various changes in form and details may be made therein without departing from the spirit and scope of the following claims.

What is claimed is:

1. An integrated circuit device, comprising:
a lower insulating film on a substrate;
a lower metal wiring layer extending in the lower insulating film in a vertical direction perpendicular to an upper surface of the substrate;
an insulating protective structure on a top surface of each of the lower metal wiring layer and the lower insulating film;
an upper insulating film on the insulating protective structure;
an upper metal wiring layer on the upper insulating film; and
a conductive contact plug extending in the upper insulating film and the insulating protective structure in the vertical direction, the conductive contact plug contacting each of the lower metal wiring layer and the upper metal wiring layer,
wherein the insulating protective structure comprises a plurality of first silicon carbonitride (SiCN) films and at least one first oxide thin film, each of which is between two adjacent ones of the plurality of first SiCN films.

2. The integrated circuit device of claim 1, wherein in the insulating protective structure, a thickness of the at least one first oxide thin film in the vertical direction is less than a thickness of each of the plurality of first SiCN films in the vertical direction.

3. The integrated circuit device of claim 1, wherein in the insulating protective structure, the at least one first oxide thin film comprises a silicon oxide film.

4. The integrated circuit device of claim 1, wherein the insulating protective structure comprises three first SiCN films and two silicon oxide films, each of the two silicon oxide films is between two adjacent ones of the three first SiCN films.

5. The integrated circuit device of claim 1, further comprising a capping insulating film between the insulating protective structure and the upper insulating film,
wherein the capping insulating film comprises a silicon oxide film, an aluminum oxide film, or a combination thereof.

6. The integrated circuit device of claim 1, further comprising an upper insulating protective structure on a top surface of each of the upper metal wiring layer and the upper insulating film,
wherein the upper insulating protective structure comprises a plurality of second SiCN films and at least one second oxide thin film, each of the at least one second oxide thin film is between two adjacent ones of the plurality of second SiCN films.

7. The integrated circuit device of claim 6, further comprising:
an interlayer insulating film on the upper insulating protective structure; and
an upper capping insulating film between the upper insulating protective structure and the interlayer insulating film,
wherein the upper capping insulating film comprises a silicon oxide film, an aluminum oxide film, or a combination thereof.

8. The integrated circuit device of claim 6, further comprising:
a thin film resistor on the upper insulating protective structure, the thin film resistor being spaced apart from the upper metal wiring layer in the vertical direction with the upper insulating protective structure therebetween; and
an insulating resistor protective structure on a top surface of the thin film resistor,
wherein the insulating resistor protective structure comprises a plurality of third SiCN films and at least one third oxide thin film, each of the at least one third oxide thin film is between two adjacent ones of the plurality of third SiCN films.

9. The integrated circuit device of claim 1, wherein each of the plurality of first SiCN films included in the insulating protective structure comprises about 40 atomic percent (at %) to about 60 at % of silicon (Si) atoms, about 20 at % to about 30 at % of carbon (C) atoms, and about 20 at % to about 30 at % of nitrogen (N) atoms.

10. An integrated circuit device, comprising:
a lower insulating film on a substrate;
a plurality of lower metal wiring layers extending in the lower insulating film in a vertical direction perpendicular to an upper surface of the substrate, the plurality of lower metal wiring layers being spaced apart from each other in a lateral direction parallel to the upper surface of the substrate;
a lower insulating protective structure on a top surface of each of the plurality of lower metal wiring layers and the lower insulating film;
an upper insulating film on the lower insulating protective structure;
an upper metal wiring layer on the upper insulating film;
a conductive contact plug extending in the upper insulating film and the insulating protective structure in the vertical direction, the conductive contact plug contacting each of a corresponding one of the plurality of lower metal wiring layers and the upper metal wiring layer; and
an upper insulating protective structure on a top surface of each of the upper metal wiring layer and the upper insulating film,
wherein each of the lower insulating protective structure and the upper insulating protective structure comprises a plurality of SiCN films and at least one oxide thin film, each of the at least one oxide thin film is between two adjacent ones of the plurality of SiCN films.

11. The integrated circuit device of claim 10, wherein in each of the lower insulating protective structure and the upper insulating protective structure, a thickness of each of the plurality of SiCN films in the vertical direction is about 4 times to about 40 times a thickness of the at least one oxide thin film in the vertical direction.

12. The integrated circuit device of claim 10, wherein in each of the lower insulating protective structure and the upper insulating protective structure, the at least one oxide thin film comprises a silicon oxide film.

13. The integrated circuit device of claim 10, wherein in each of the lower insulating protective structure and the upper insulating protective structure, the plurality of SiCN films have a same content ratio of carbon (C) atoms.

14. The integrated circuit device of claim 10, wherein in each of the lower insulating protective structure and the upper insulating protective structure, a content ratio of carbon (C) atoms in a first one of the plurality of SiCN films is different from a content ratio of carbon atoms in a second one of the plurality of SiCN films.

15. The integrated circuit device of claim 10, wherein each of the lower insulating protective structure and the upper insulating protective structure comprises three SiCN films and two silicon oxide films, each of the two silicon oxide films is between two adjacent ones of the three SiCN films.

16. The integrated circuit device of claim 10, further comprising:
a lower capping insulating film contacting a top surface of the lower insulating protective structure; and
an upper capping insulating film contacting a top surface of the upper insulating protective structure,
wherein each of the lower capping insulating film and the upper capping insulating film comprises a silicon oxide film, an aluminum oxide film, or a combination thereof.

17. The integrated circuit device of claim 10, further comprising:
a thin film resistor on the upper insulating protective structure, the thin film resistor being spaced apart from the upper metal wiring layer with the upper insulating protective structure therebetween in the vertical direction; and
an insulating resistor protective structure contacting a top surface of the thin film resistor,
wherein at least a portion of the insulating resistor protective structure has a same configuration as a portion of the lower insulating protective structure or a portion of the upper insulating protective structure.

18. An integrated circuit device, comprising:
a lower insulating film on a substrate;
a plurality of lower metal wiring layers extending in the lower insulating film in a vertical direction perpendicular to an upper surface of the substrate, the plurality of lower metal wiring layers being spaced apart from each other in a lateral direction parallel to the upper surface of the substrate;
a lower insulating protective structure on a top surface of each of the plurality of lower metal wiring layers and the lower insulating film;
an upper insulating film on the lower insulating protective structure;
an upper metal wiring layer on the upper insulating film;
a conductive contact plug extending in the upper insulating film and the insulating protective structure in the vertical direction, the conductive contact plug contacting each of a corresponding one of the plurality of lower metal wiring layers and the upper metal wiring layer;
an upper insulating protective structure on a top surface of each of the upper metal wiring layer and the upper insulating film;
a thin film resistor on the upper insulating protective structure, the thin film resistor spaced apart from the upper metal wiring layer with the upper insulating protective structure therebetween in the vertical direction; and
an insulating resistor protective structure contacting a top surface of the thin film resistor,
wherein each of the lower insulating protective structure, the upper insulating protective structure, and the insulating resistor protective structure comprises a plurality of SiCN films and at least one oxide thin film, each of the at least one oxide thin film is between two adjacent ones of the plurality of SiCN films.

19. The integrated circuit device of claim 18, wherein in each of the lower insulating protective structure, the upper insulating protective structure, and the insulating resistor protective structure, a thickness of each of the plurality of SiCN films in the vertical direction is in a range of about 2 nm to about 10 nm, and a thickness of the at least one oxide thin film in the vertical direction is in a range of about 0.3 nm to about 0.5 nm, and
in each of the lower insulating protective structure, the upper insulating protective structure, and the insulating resistor protective structure, the plurality of SiCN films have a same content ratio of carbon (C) atoms.

20. The integrated circuit device of claim 18, wherein in each of the lower insulating protective structure, the upper insulating protective structure, and the insulating resistor protective structure, a thickness of each of the plurality of SiCN films in the vertical direction is in a range of about 2 nm to about 10 nm, and a thickness of the at least one oxide thin film in the vertical direction is in a range of about 0.3 nm to about 0.5 nm, and
in each of the lower insulating protective structure, the upper insulating protective structure, and the insulating resistor protective structure, a content ratio of carbon atoms in at least a first one of the plurality of SiCN films is different from a content ratio of carbon atoms in a second one of the plurality of SiCN films.
